(19) United States
(12) Patent Application Publication
(10) Pub. No.: US 2016/0209326 A1
(43) Pub. Date: Jul. 21, 2016

(54) SPATIALLY-RESOLVED MONITORING OF FABRICATION OF INTEGRATED COMPUTATIONAL ELEMENTS

(71) Applicant: HALLIBURTON ENERGY SERVICES, INC., Houston, TX (US)

(72) Inventors: David L. PERKINS, The Woodlands, TX (US); Robert Paul FREESE, Pittsboro, NC (US); Christopher Michael JONES, Houston, TX (US); Richard Neal GARDNER, Raleigh, NC (US)

(73) Assignee: HALLIBURTON ENERGY SERVICES, INC., Houston, TX (US)

(21) Appl. No.: 14/400,210

(22) PCT Filed: Dec. 24, 2013
(86) PCT No.: PCT/US2013/077688

§ 371 Date: Nov. 10, 2014

(51) Int. Cl. G01N 21/41; C23C 14/22; G01B 11/06

(52) U.S. Cl. CPC G01N 21/41; G01B 11/06; C23C 14/22; G01N 2201/12

(57) ABSTRACT

Techniques include receiving a design of an integrated computational element (ICE) including specification of a substrate and multiple layers, their respective target thicknesses and complex refractive indices, complex refractive indices of adjacent layers being different from each other, and a notional ICE fabricated based on the ICE design being related to a characteristic of a sample; forming at least some of the layers of a plurality of ICEs in accordance with the ICE design, where the ICEs' layers are moved along a direction of motion during the forming; measuring characteristics of probe-light that interacts with formed ICEs' layers such that the measured characteristics are spatially-resolved along a first direction orthogonal to the direction of motion; determining, based on the spatially-resolved characteristics, complex refractive indices and thicknesses of the formed ICE layers as a function of the ICEs' location along the first direction; adjusting the forming based on the determinations.

### BACKGROUND

The subject matter of this disclosure is generally related to fabrication of an integrated computational element (ICE) used in optical analysis tools for analyzing a substance of interest, for example, crude petroleum, gas, water, or other wellbore fluids. For instance, the disclosed ICE fabrication uses spatially-resolved measurement techniques for in-situ monitoring of the ICE fabrication.

Information about a substance can be derived through the interaction of light with that substance. The interaction changes characteristics of the light, for instance the frequency (and corresponding wavelength), intensity, polarization, and/or direction (e.g., through scattering, absorption, reflection or refraction). Chemical, thermal, physical, mechanical, optical or various other characteristics of the substance can be determined based on the changes in the characteristics of the light interacting with the substance. As such, in certain applications, one or more characteristics of crude petroleum, gas, water, or other wellbore fluids can be derived in-situ, e.g., downhole at well sites, as a result of the interaction between these substances and light.

Integrated computational elements (ICEs) enable the measurement of various chemical or physical characteristics through the use of regression techniques. An ICE selectively weights, when operated as part of optical analysis tools, light modified by a sample in at least a portion of a wavelength range such that the weightings are related to one or more characteristics of the sample. An ICE can be an optical substrate with multiple stacked dielectric layers (e.g., from about 2 to about 50 layers), each having a different complex refractive index from its adjacent layers. The specific number of layers, N, the optical properties (e.g. real and imaginary components of complex indices of refraction) of the layers, the optical properties of the substrate, and the physical thickness of each of the layers that compose the ICE are selected so that the light processed by the ICE is related to one or more characteristics of the sample. Because ICEs extract information from the light modified by a sample passively, they can be incorporated in low cost and rugged optical analysis tools. Hence, ICE-based downhole optical analysis tools can provide a relatively low cost, rugged and accurate system for monitoring quality of wellbore fluids, for instance.

Errors in fabrication of some constituent layers of an ICE design can degrade the ICE's target performance. In most cases, deviations of <0.1%, and even 0.01% or 0.0001%, from point by point design values of the optical characteristics (e.g., complex refractive indices), and/or physical characteristics (e.g., thicknesses) of the formed layers of the ICE can reduce the ICE's performance, in some cases to such an extent, that the ICE becomes operationally useless. For example, non-uniformities in the spatial-profile of a deposition plume provided by a deposition source lead to corresponding non-uniformities of complex refractive indices and thicknesses of the formed layers of ICEs that are spatially distributed relative the deposition source within a fabrication batch. To prevent degradation of ICE performance due to the noted non-uniformities, the ICEs being fabricated are often moved (sometimes periodically) relative to the deposition source along a direction of motion along which the spatial-profile of the deposition plume is non-uniform. Conventionally, complex refractive indices and thicknesses of layers of a fabricated ICE are determined by performing in-situ measurements during fabrication of the ICEs at a single location located either along the direction of motion or at a particular lateral distance from the direction of motion. Those familiar or currently practicing in the art will readily appreciate that the ultra-high accuracies required by ICE designs challenge the state of the art in spatially-resolved measurement techniques used for monitoring thin film fabrication.

### DESCRIPTION OF DRAWINGS

FIGS. 1A-1C show multiple configurations of an example of a system for analyzing wellbore fluids that uses a well logging tool including an ICE.

FIG. 2 is a flowchart showing an example of a process for designing an ICE.

FIGS. 3A-3B show configurations of an example of a system for ICE fabrication that has an associated measurement system used to perform spatially-resolved measurements for in-situ monitoring the ICE fabrication.

FIGS. 4-5 show aspects of the ICE fabrication system shown in FIGS. 3A-3B.

FIGS. 6A-6C are flowcharts showing aspects of an example of an ICE fabrication process that uses in-situ monitoring based on spatially-resolved measurements.

Like reference symbols in the various drawings indicate like elements.

### DETAILED DESCRIPTION

Technologies are described for forming layers of ICEs by moving the ICEs along a direction of motion and in-situ monitoring the forming of the ICE layers at various locations along a direction orthogonal to the direction of motion. Such spatially-resolved (or location-dependent) monitoring enables accurate determinations of complex refractive indices and thicknesses of the formed layers of the ICEs within a fabrication batch. In some implementations, completion of each of the ICE layers is triggered, on an ICE-by-ICE manner, when the determined thickness of an ICE layer for an ICE located at a given lateral distance from the direction of motion along the orthogonal direction matches an associated target thickness. In other implementations, when the completion of each of the ICE layers is triggered based on statistics of the determined complex refractive indices and thicknesses over the entire batch, fabricated ICEs can be sorted and binned based on their locations along the direction orthogonal to the direction of motion.

The complex refractive indices and thicknesses of the formed layers determined from results of the disclosed spatially-resolved monitoring are potentially more accurate than if they were conventionally determined from results of conventional in-situ monitoring performed at a fixed location relative to the direction of motion. As values of the determined complex refractive indices and thicknesses of the formed layers are used to adjust forming of layers of the ICEs remaining to be formed, the more accurate in-situ monitoring of the disclosed ICE fabrication translates into improved batch yield and yield consistency batch-to-batch relative to conventional ICE fabrication.

Prior to describing example implementations of the disclosed technologies for ICE fabrication, the following technologies are described below: in Section (1)—optical analysis tools based on ICE along with examples of their use in oil/gas exploration, and in Section (2)—techniques for designing an ICE.

### (1) ICE-Based Analysis of Wellbore Fluids

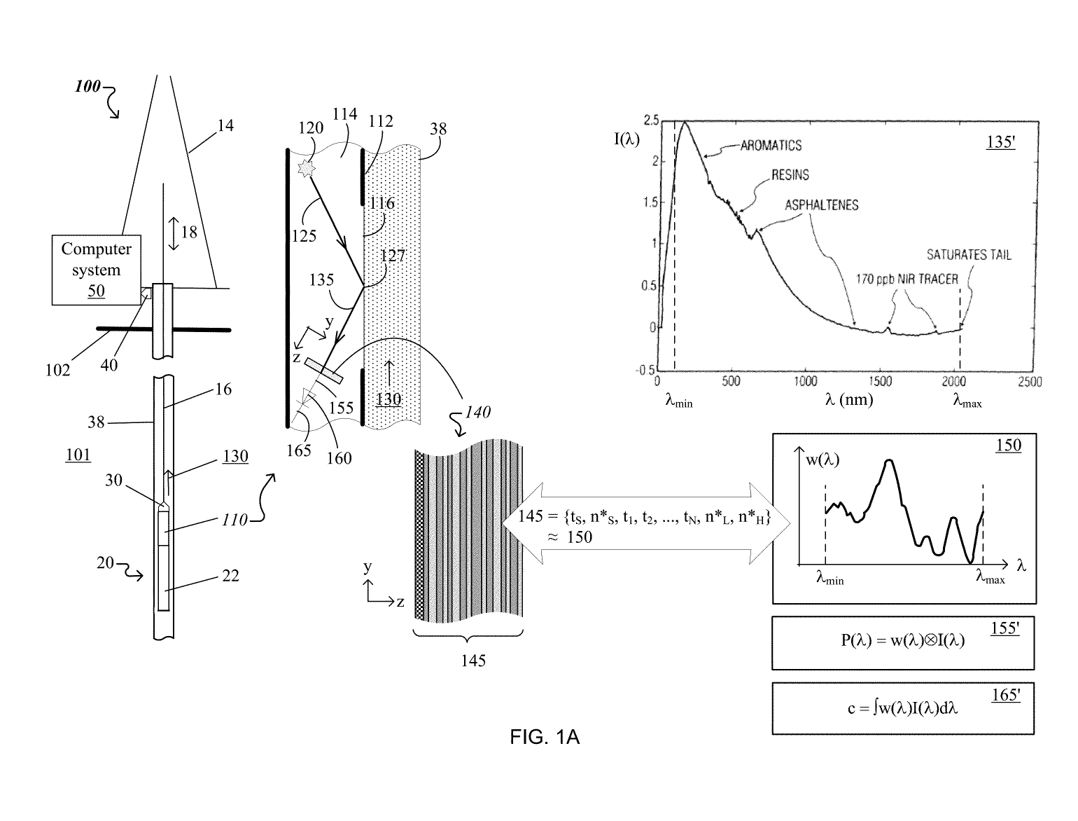

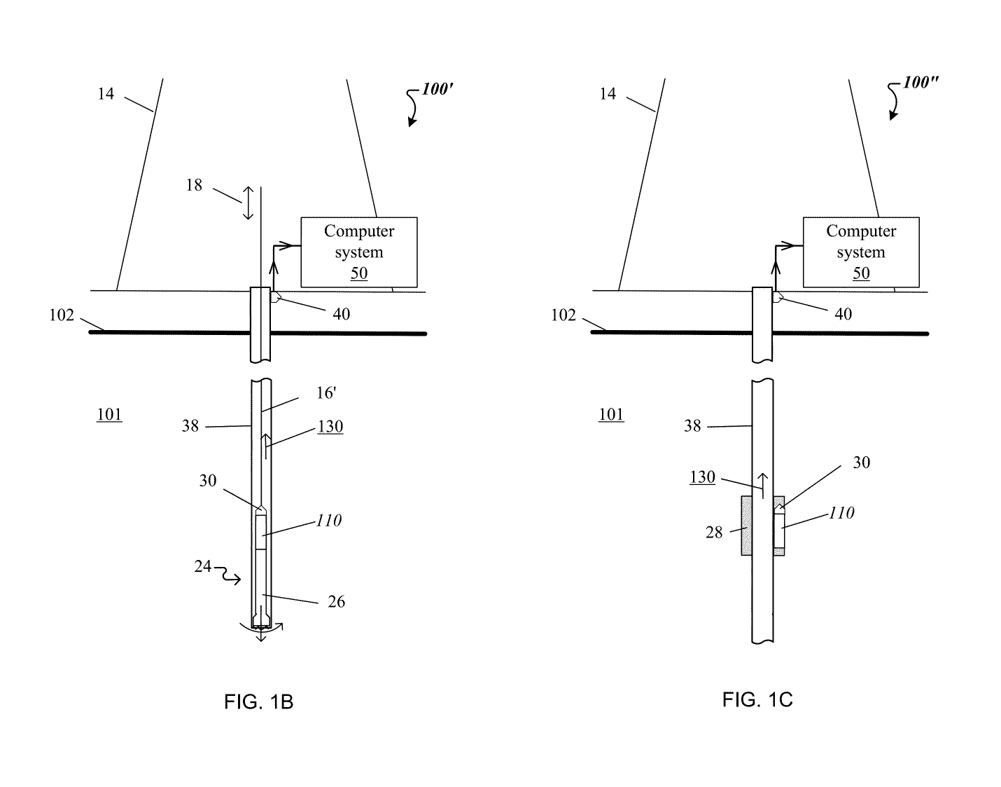

FIGS. 1A-1C show multiple configurations 100, 100′, 100″ of an example of a system for analyzing wellbore fluids 130, such that analyses are generated from measurements taken with a well logging tool 110 configured as an ICE-based optical analysis tool. The disclosed system also is referred to as a well logging system.

Each of the configurations 100, 100′, 100″ of the well logging system illustrated in FIGS. 1A-1C includes a rig 14 above the ground surface 102 and a wellbore 38 below the ground surface. The wellbore 38 extends from the ground surface into the earth 101 and generally passes through multiple geologic formations. In general, the wellbore 38 can contain wellbore fluids 130. The wellbore fluids 130 can be crude petroleum, mud, water or other substances and combinations thereof. Moreover, the wellbore fluids 130 may be at rest, or may flow toward the ground surface 102, for instance. Additionally, surface applications of the well logging tool 110 may include water monitoring and gas and crude transportation and processing.

FIG. 1A shows a configuration 100 of the well logging system which includes a tool string 20 attached to a cable 16 that can be lowered or raised in the wellbore 38 by draw works 18. The tool string 20 includes measurement and/or logging tools to generate and log information about the wellbore fluids 130 in the wellbore 38. In the configuration 100 of the well logging system, this information can be generated as a function of a distance (e.g., a depth) with respect to the ground surface 102. In the example illustrated in FIG. 1A, the tool string 20 includes the well logging tool 110, one or more additional well logging tool(s) 22, and a telemetry transmitter 30. Each of the well logging tools 110 and 22 measures one or more characteristics of the wellbore fluids 130. In some implementations, the well logging tool 110 determines values of the one or more characteristics in real time and reports those values instantaneously as they occur in the flowing stream of wellbore fluids 130, sequentially to or simultaneously with other measurement/logging tools 22 of the tool string 20.

FIG. 1B shows another configuration 100′ of the well logging system which includes a drilling tool 24 attached to a drill string 16′. The drilling tool 24 includes a drill bit 26, the ICE-based well logging tool 110 configured as a measurement while drilling (MWD) and/or logging while drilling (LWD) tool, and the telemetry transmitter 30. Drilling mud is provided through the drill string 16′ to be injected into the borehole 38 through ports of the drill bit 26. The injected drilling mud flows up the borehole 38 to be returned above the ground level 102, where the returned drilling mud can be resupplied to the drill string 16′ (not shown in FIG. 1B). In this case, the MWD/LWD-configured well logging tool 110 generates and logs information about the wellbore fluids 130 (e.g., drilling mud in this case) adjacent the working drill bit 26.

FIG. 1C shows yet another configuration 100″ of the well logging system which includes a permanent installation adjacent to the borehole 38. In some implementations, the permanent installation is a set of casing collars that reinforce the borehole 38. In this case, a casing collar 28 from among the set of casing collars supports the well logging tool 110 and the telemetry transmitter 30. In this manner, the well logging tool 110 determines and logs characteristics of the wellbore fluids 130 adjacent the underground location of the casing collar 28.

In each of the above configurations 100, 100′ and 100″ of the well logging system, the values of the one or more characteristics measured by the well logging tool 110 are provided (e.g., as a detector signal 165) to the telemetry transmitter 30. The latter communicates the measured values to a telemetry receiver 40 located above the ground surface 102. The telemetry transmitter 30 and the telemetry receiver 40 can communicate through a wired or wireless telemetry channel. In some implementations of the system configurations 100, 100′ illustrated in FIGS. 1A and 1B, e.g., in slickline or coiled tubing applications, measurement data generated by the well logging tool 110 can be written locally to memory of the well logging tool 110.

The measured values of the one or more characteristics of the wellbore fluids 130 received by the telemetry receiver 40 can be logged and analyzed by a computer system 50 associated with the rig 14. In this manner, the measurement values provided by the well logging tool 110 can be used to generate physical and chemical information about the wellbore fluids 130 in the wellbore 38.

Referring again to FIG. 1A, the well logging tool 110 includes a light source 120, an ICE 140 and an optical transducer 160. The well logging tool 110 has a frame 112 such that these components are arranged in an enclosure 114 thereof. A cross-section of the well logging tool 110 in a plane perpendicular to the page can vary, depending on the space available. For example, the well logging tool's cross-section can be circular or rectangular, for instance. The well logging tool 110 directs light to the sample 130 through an optical interface 116, e.g., a window in the frame 112. The well logging tool 110 is configured to probe the sample 130 (e.g., the wellbore fluids stationary or flowing) in the wellbore 38 through the optical interface 116 and to determine an amount (e.g., a value) of a given characteristic (also referred to as a characteristic to be measured) of the probed sample 130. The characteristic to be measured can be any one of multiple characteristics of the sample 130 including concentration of a given substance in the sample, a gas-oil-ratio (GOR), pH value, density, viscosity, etc.

The light source 120 outputs light with a source spectrum over a particular wavelength range, from a minimum wavelength λₘᵢₙ to a maximum wavelength λₘₐₓ. In some implementations, the source spectrum can have non-zero intensity over the entire or most of the wavelength range λₘₐₓ-λₘᵢₙ. In some implementations, the source spectrum extends through UV-vis (0.2-0.8 μm) and near-IR (0.8-2.5 μm) spectral ranges. Alternatively, or additionally, the source spectrum extends through near-IR and mid-IR (2.5-25 μm) spectral ranges. In some implementations, the source spectrum extends through near-IR, mid-IR and far-IR (25-100 μm) spectral ranges. In some implementations, the light source 120 is tunable and is configured in combination with time resolved signal detection and processing.

The light source 120 is arranged to direct a probe beam 125 of the source light towards the optical interface 116 where it illuminates the sample 130 at a location 127. The source light in the probe beam 125 interacts with the sample 130 and reflects off it as light modified by the sample 130. The light modified by the sample has a modified spectrum I(λ) 135′ over the particular wavelength range. In the reflective configuration of the well logging tool 110 illustrated in FIG. 1A (i.e., where the light to be analyzed reflects at the sample/window interface), the modified spectrum I(λ) 135′ is a reflection spectrum associated with the sample 130. In a transmission configuration of the well logging tool 110 (not shown in FIG. 1A), the probe beam is transmitted through the sample as modified light, such that the modified spectrum I(λ) 135′ is a transmission spectrum associated with the sample.

In general, the modified spectrum I(λ) 135′ encodes information about multiple characteristics associated with the sample 130, and more specifically the encoded information relates to current values of the multiple characteristics. In the example illustrated in FIG. 1A, the modified spectrum 135′ contains information about one or more characteristics of the wellbore fluids 130.

With continued reference to FIG. 1A, and the Cartesian coordinate system provided therein for reference, the ICE 140 is arranged to receive a beam 135 of the sample modified light, and is configured to process it and to output a beam 155 of processed light. The beam 135 of sample modified light is incident on a first surface of the ICE 140 along the z-axis, and the beam 155 of processed light is output along the z-axis after transmission through the ICE 140. Alternatively or additionally, the beam 155 (or an additional reflected beam) of processed light can be output after reflection off the first surface of the ICE 140. The ICE 140 is configured to process the sample modified light by weighting it in accordance with an optical spectrum w(λ) 150 associated with a characteristic to be measured.

The optical spectrum w(λ) 150 is determined offline by applying conventional processes to a set of calibration spectra I(λ) of the sample which correspond to respective known values of the characteristic to be measured. As illustrated by optical spectrum w(λ) 150, optical spectrums generally may include multiple local maxima (peaks) and minima (valleys) between λₘᵢₙ and λₘₐₓ. The peaks and valleys may have the same or different amplitudes. For instance, an optical spectrum w(λ) can be determined through regression analysis of N_{c} calibration spectra Iⱼ(λ) of a sample, where j=1, . . . , N_{c}, such that each of the calibration spectra Iⱼ(λ) corresponds to an associated known value of a given characteristic for the sample. A typical number N_{c} of calibration spectra Iⱼ(λ) used to determine the optical spectrum w(λ) 150 through such regression analysis can be N_{c}=10, 40 or 100, for instance. The regression analysis outputs, within the N_{c} calibration spectra Iⱼ(λ), a spectral pattern that is unique to the given characteristic. The spectral pattern output by the regression analysis corresponds to the optical spectrum w(λ) 150. In this manner, when a value of the given characteristic for the sample is unknown, a modified spectrum Iᵤ(λ) of the sample is acquired by interacting the probe beam 125 with the sample 130, then the modified spectrum Iᵤ(L) is weighted with the ICE 140 to determine a magnitude of the spectral pattern corresponding to the optical spectrum w(λ) 150 within the modified spectrum Iᵤ(λ). The determined magnitude is proportional to the unknown value of the given characteristic for the sample.

For example, the sample can be a mixture (e.g., the wellbore fluid 130) containing substances X, Y and Z, and the characteristic to be measured for the mixture is concentration cx of substance X in the mixture. In this case, N_{c} calibration spectra Iⱼ(λ) were acquired for N_{c} samples of the mixture having respectively known concentration values for each of the substances contained in the N_{c} samples. By applying regression analysis to the N_{c} calibration spectra Iⱼ(λ), a first spectral pattern that is unique to the concentration cx of the X substance can be detected (recognized), such that the first spectral pattern corresponds to a first optical spectrum w_{cX}(λ) associated with a first ICE, for example. Similarly, second and third spectral patterns that are respectively unique to concentrations c_{Y} and c_{Z} of the Y and Z substances can also be detected, such that the second and third spectral patterns respectively correspond to second and third optical spectra w_{cY}(λ) and w_{cZ}(λ) respectively associated with second and third ICEs. In this manner, when a new sample of the mixture (e.g., the wellbore fluid 130) has an unknown concentration c_{X} of the X substance, for instance, a modified spectrum Iᵤ(λ) of the new sample can be acquired by interacting the probe beam with the mixture, then the modified spectrum Iᵤ(λ) is weighted with the first ICE to determine a magnitude of the first spectral pattern within the modified spectrum Iᵤ(λ). The determined magnitude is proportional to the unknown value of the concentration c_{X} of the X substance for the new sample.

Referring again to FIG. 1A, the ICE 140 includes N layers of materials stacked on a substrate, such that complex refractive indices of adjacent layers are different from each other. The total number of stacked layers can be between 6 and 50, for instance. The substrate material can be BK7, diamond, Ge, ZnSe (or other transparent dielectric material), and can have a thickness in the range of 0.02-2 mm, for instance, to insure structural integrity of the ICE 140.

Throughout this specification, a complex index of refraction (or complex refractive index) n* of a material has a complex value, Re(n*)+iIm(n*). Re(n*) represents a real component of the complex index of refraction responsible for refractive properties of the material, and Im(n*) represents an imaginary component of the complex index of refraction (also known as extinction coefficient κ) responsible for absorptive properties of the material. In this specification, when it is said that a material has a high complex index of refraction n*_{H} and another material has a low complex index of refraction n*_{L}, the real component Re(n*_{H}) of the high complex index of refraction n*_{H} is larger than the real component Re(n*_{L}) of the low complex index of refraction n*_{L}, Re(n*_{H})>Re(n*_{L}). Materials of adjacent layers of the ICE are selected to have a high complex index of refraction n*_{H} (e.g., Si), and a low complex index of refraction n*_{L} (e.g., SiO₂). Here, Re(n*_{Si})≈2.4>Re(n*_{SiO2})≈1.5. For other material pairings, however, the difference between the high complex refractive index n*_{H} and low complex refractive index n*_{L} may be much smaller, e.g., Re(n*_{H})≈1.6>Re(n*_{L})≈1.5. The use of two materials for fabricating the N layers is chosen for illustrative purposes only. For example, a plurality of materials having different complex indices of refraction, respectively, can be used. Here, the materials used to construct the ICE are chosen to achieve a desired optical spectrum w(λ) 150.

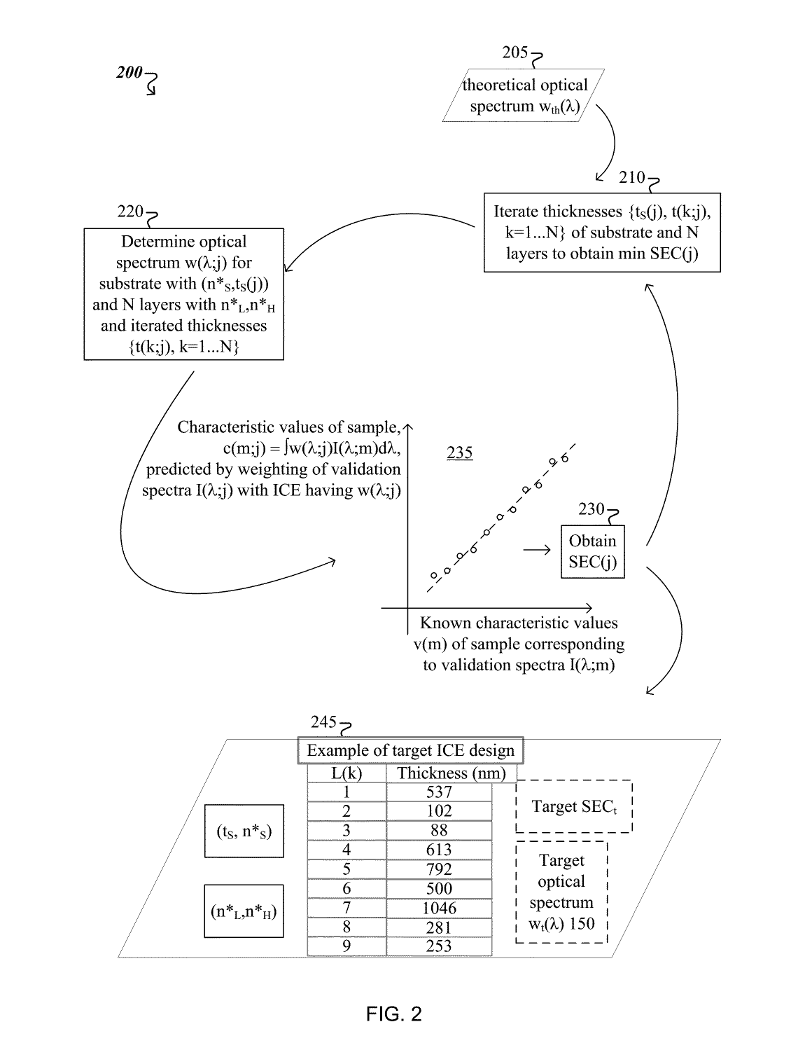

A set of design parameters 145—which includes the total number of stacked layers N, the complex refractive indices n*_{H}, n*_{L} of adjacent stacked layers, and the thicknesses of the N stacked layers t(1), t(2), t(N−1), t(N)—of the ICE 140 can be chosen (as described below in connection with FIG. 2) to be spectrally equivalent to the optical spectrum w(λ) 150 associated with the characteristic to be measured. As such, an ICE design includes a set 145 of thicknesses {t(i), i=1, . . . , N} of the N layers stacked on the substrate that correspond to the optical spectrum w(λ) 150.

In view of the above, the beam 155 of processed light output by the ICE 140 has a processed spectrum P(λ)=*w(λ)\textcircled{×}I(λ)155′ over the wavelength range λₘₐₓ-λₘᵢₙ, such that the processed spectrum 155′ represents the modified spectrum I(λ) 135′ weighted by the optical spectrum w(λ) 150 associated with the characteristic to be measured.

The beam 155 of processed light is directed from the ICE 140 to the optical transducer 160, which detects the processed light and outputs an optical transducer signal 165. A value (e.g., a voltage) of the optical transducer signal 165 is a result of an integration of the processed spectrum 155′ over the particular wavelength range and is proportional to the unknown value “c” 165′ of the characteristic to be measured for the sample 130.

In some implementations, the well logging tool 110 can include a second ICE (not shown in FIG. 1A) associated with a second ICE design that includes a second set of thicknesses {t′(i), i=1, . . . , N′} of a second total number N′ of layers, each having a different complex refractive index from its adjacent layers, the complex refractive indices and the thicknesses of the N′ layers corresponding to a second optical spectrum w′(λ). Here, the second optical spectrum w′(λ) is associated with a second characteristic of the sample 130, and a second processed spectrum represents the modified spectrum I(λ) 135′ weighted by the second optical spectrum w′(λ), such that a second value of a second detector signal is proportional to a value of the second characteristic for the sample 130.

In some implementations, the determined value 165′ of the characteristic to be measured can be logged along with a measurement time, geo-location, and other metadata, for instance. In some implementations, the detector signal 165, which is proportional to a characteristic to be measured by the well logging tool 110, can be used as a feedback signal to adjust the characteristic of the sample, to modify the sample or environmental conditions associated with the sample, as desired.

Characteristics of the wellbore fluids 130 that can be related to the modified spectrum 135′ through the optical spectra associated with the ICE 140 and other ICEs (not shown in FIG. 1A) are concentrations of one of asphaltene, saturates, resins, aromatics; solid particulate content; hydrocarbon composition and content; gas composition C1-C6 and content: CO₂, H₂S and correlated PVT properties including GOR, bubble point, density; a petroleum formation factor; viscosity; a gas component of a gas phase of the petroleum; total stream percentage of water, gas, oil, solid articles, solid types; oil finger printing; reservoir continuity; oil type; and water elements including ion composition and content, anions, cations, salinity, organics, pH, mixing ratios, tracer components, contamination, or other hydrocarbon, gas, solids or water property.

### (2) Aspects of ICE Design

Aspects of a process for designing an ICE associated with a characteristic to be measured (e.g., one of the characteristics enumerated above) are described below. Here, an input of the ICE design process is a theoretical optical spectrum wₜₕ(λ) associated with the characteristic. An output of the ICE design process is an ICE design that includes specification of (1) a substrate and a number N of layers to be formed on the substrate, each layer having a different complex refractive index from its adjacent layers; and (2) complex refractive indices and thicknesses of the substrate and layers that correspond to a target optical spectrum wₜ(λ). The target optical spectrum wₜ(λ) is different from the theoretical optical spectrum wₜₕ(λ) associated with the characteristic, such that the difference between the target and theoretical optical spectra cause degradation of a target performance relative to a theoretical performance of the ICE within a target error tolerance. The target performance represents a finite accuracy with which an ICE having the target optical spectrum wₜ(λ) is expected to predict known values of the characteristic corresponding to a set of validation spectra of a sample with a finite (non-zero) error. Here, the predicted values of the characteristic are obtained through integration of the validation spectra of the sample respectively weighted by the ICE with the target optical spectrum wₜ(λ). The theoretical performance represents the maximum accuracy with which the ICE—if it had the theoretical optical spectrum wₜₕ(λ)—would predict the known values of the characteristic corresponding to the set of validation spectra of the sample. Here, the theoretically predicted values of the characteristic would be obtained through integration of the validation spectra of the sample respectively weighted by the ICE, should the ICE have the theoretical optical spectrum wₜₕ(λ).

FIG. 2 is a flow chart of an example of a process 200 for generating an ICE design. One of the inputs to the process 200 is a theoretical optical spectrum wₜₕ(λ) 205. For instance, to design an ICE for measuring concentration of a substance X in a mixture, a theoretical optical spectrum wₜₕ(λ) associated with the concentration of the substance X in the mixture, is accessed, e.g., in a data repository. As described above in this specification, the accessed theoretical optical spectrum wₜ(λ) corresponds to a spectral pattern detected offline, using a number N_{c} of calibration spectra of the mixture, each of the N_{c} calibration spectra corresponding to a known concentration of the substance X in the mixture. An additional input to the process 200 is a specification of materials for a substrate and ICE layers. Materials having different complex refractive indices, respectively, are specified such that adjacent ICE layers are formed from materials with different complex refractive indices. For example, a first material (e.g., Si) having a high complex refractive index n*_{H} and a second material (e.g., SiOₓ) having a low complex refractive index n*_{L} are specified to alternately form the ICE layers. As another example, a layer can be made from high index material (e.g., Si), followed by a layer made from low index material (e.g., SiOₓ), followed by a layer made from a different high index material (e.g., Ge), followed by a layer made from a different low index material (MgF₂), etc. The iterative design process 200 is performed in the following manner.

At 210 during the j^{th} iteration of the design process 200, thicknesses {ts(j), t(1;j), t(2;j), t(N−1;j), t(N;j)} of the substrate and a number N of layers of the ICE are iterated.

At 220, a j^{th} optical spectrum w(λ;j) of the ICE is determined corresponding to complex refractive indices and previously iterated thicknesses {ts(j), t(1;j), t(2;j), t(N−1;j), t(N;j)} of the substrate and the N layers, each having a different complex refractive index from its adjacent layers. The iterated thicknesses of the substrate and the N layers are used to determine the corresponding j^{th} optical spectrum w(λ;j) of the ICE in accordance with conventional techniques for determining spectra of thin film interference filters.

At 230, performance of the ICE, which has the j^{th} optical spectrum w(λ;j) determined at 220, is obtained. To do so, a set of validation spectra of a sample is accessed, e.g., in a data repository. Respective values of a characteristic of the sample are known for the validation spectra. For instance, each of Nᵥ validation spectra I(λ;m) corresponds to a value v(m) of the characteristic of the sample, where m=1, . . . , Nᵥ. In the example illustrated in FIG. 2, Nᵥ=11 validation spectra, respectively corresponding to 11 known values of the characteristic to be measured for the sample, are being used.

Graph 235 shows (in open circles) values c(m;j) of the characteristic of the sample predicted by integration of the validation spectra I(λ;m) weighted with the ICE, which has the j^{th} optical spectrum w(λ;j), plotted against the known values v(m) of the characteristic of the sample corresponding to the validation spectra I(λ;m). The predicted values c(m;1) of the characteristic are found by substituting, in formula 165′ of FIG. 1A, (1) the spectrum I(λ) 135′ of sample modified light with the respective validation spectra I(2;m) and (2) the target spectrum wₜ(λ) 150 with the j^{th} optical spectrum w(λ;j). In this example, performance of the ICE, which has the j^{th} optical spectrum w(λ;j), is quantified in terms of a weighted measure of distances from each of the open circles in graph 325 to the dashed-line bisector between the x and y axes. This weighted measure is referred to as the standard calibration error (SEC) of the ICE. For instance, an ICE having the theoretical spectrum wₜₕ(λ) has a theoretical SECₜₕ that represents a lower bound for the SEC(j) of the ICE having the j^{th} spectrum w(λ;j) determined at 220 during the j^{th} iteration of the design process 200: SEC(j)>SECₜₕ.

In this specification, the SEC is chosen as a metric for evaluating ICE performance for the sake of simplicity. Note that there are other figures of merit that may be used to evaluate performance of ICE, as is known in the art. For example, sensitivity—which is defined as the slope of characteristic change as a function of signal strength—can also be used to evaluate ICE performance. As another example, standard error of prediction (SEP)—which is defined in a similar manner to the SEC except it uses a different set of validation spectra—can be used to evaluate ICE performance. Any of the figure(s) of merit known in the art is/are evaluated in the same general way by comparing theoretical performance with that actually achieved. Which figure(s) of merit or combinations are used to evaluate ICE performance is determined by the specific ICE design.

The iterative design process 200 continues by iterating, at 210, the thicknesses of the substrate and the N layers. The iterating is performed such that a (j+1)th optical spectrum w(λ;j+1)—determined at 220 from the newly iterated thicknesses—causes, at 230, improvement in performance of the ICE, to obtain SEC(j+1)<SEC(j). In some implementations, the iterative design process 200 is stopped when the ICE's performance reaches a local maximum, or equivalently, the SEC of the ICE reaches a local minimum. For example, the iterative process 200 can be stopped at the (j+1)^{th} iteration when the current SEC(j+1) is larger than the last SEC(j), SEC(j+1)>SEC(j). In some implementations, the iterative design process 200 is stopped when, for a given number of iterations, the ICE's performance exceeds a specified threshold performance for a given number of iterations. For example, the iterative design process 200 can be stopped at the j^{th} iteration when three consecutive SEC values decrease monotonously and are less than a specified threshold value:

SEC₀>SEC(j−2)>SEC(j−1)>SEC(j).

In either of these cases, an output of the iterative process 200 represents a target ICE design 245 to be used for fabricating an ICE 140, like the one described in FIG. 1A, for instance. The ICE design 245 includes specification of (1) a substrate and N layers, each having a different complex refractive index from its adjacent layers, and (2) complex refractive indices n*_{S}, n*_{H}, n*_{L} and thicknesses {ts(j), t(1;j), t(2;j), t(N−1;j), t(N;j)} of the substrate and N layers corresponding to the j^{th} iteration of the process 200. Additional components of the ICE design are the optical spectrum w(λ;j) and the SEC(j)—both determined during the j^{th} iteration based on the thicknesses {ts(j), t(1;j), t(2;j), t(N−1;j), t(N;j)}. As the ICE design 245 is used as input for fabrication processes described herein, the iteration index j—at which the iterative process 200 terminates—is dropped from the notations used for the components of the ICE design.

In this manner, the thicknesses of the substrate and the N layers associated with the ICE design 245 are denoted {ts, t(1), t(2), t(N−1), t(N)} and are referred to as the target thicknesses. The optical spectrum associated with the ICE design 245 and corresponding to the target thicknesses is referred to as the target optical spectrum wₜ(λ) 150. The SEC associated with the ICE design 245—obtained in accordance with the target optical spectrum wₜ(λ) 150 corresponding to the target thicknesses—is referred to as the target SECₜ. In the example illustrated in FIG. 2, the ICE design 245 has a total of N=9 alternating Si and SiO₂ layers, with complex refractive indices n_{Si}, n_{SiO2}, respectively. The layers' thicknesses (in nm) are shown in the table. An ICE fabricated based on the example of ICE design 245 illustrated in FIG. 2 is used to predict value(s) of concentration of substance X in wellbore fluids 130.

### (3) Technologies for Adjusting Fabrication of ICE

As described above in connection with FIG. 2, an ICE design specifies a number of material layers), each having a different complex refractive index from its adjacent layers. An ICE fabricated in accordance with the ICE design has (i) a target optical spectrum wₜ(λ) and (ii) a target performance SECₜ, both of which corresponding to the complex refractive indices and target thicknesses of a substrate and a total number of layers specified by the ICE design. Performance of the ICE fabricated in accordance with the ICE design can be very sensitive to actual values of the complex refractive indices and thicknesses obtained during deposition. For a wide variety of reasons, the actual values of the complex refractive indices of materials to be deposited and/or the rate(s) of the deposition may drift within a fabrication batch or batch-to-batch, or may be affected indirectly by errors caused by measurement systems used to control the foregoing fabrication parameters. For example, materials used for deposition (Si, SiO₂) may be differently contaminated, or react differently due to different chamber conditions (e.g., pressure or temperature). For some layers of the ICE design 245, a small error, e.g., 0.1% or 0.001%, in the thickness of a deposited layer can result in a reduction in the performance of an ICE associated with the ICE design 245 below an acceptable threshold.

Thickness and complex refractive index uniformity of deposited layers can be controlled across a batch of ICEs being fabricated by moving a support—that supports these ICEs during fabrication—along a direction of motion with respect to a deposition source. Typically, the direction of motion is chosen to match a direction along which a spatial profile of a deposition plume of the deposition source is non-uniform. However, actual values of complex refractive indices and/or thicknesses of deposited layers can be different from their target values due to deposition rate drifts (i) during fabrication of one or more layers of the ICEs fabricated within a batch, or (ii) from batch-to-batch. For example, deposition rate changes may be caused by contamination of materials used for deposition (Si, SiO₂), or by modifications of deposition chamber conditions (e.g., pressure or temperature). The deposition rate changes can lead to changes in thicknesses and/or complex refractive indices of the deposited layers compared to their respective targets, which in turn result in degradation of the fabricated ICEs' performance with respect to a target performance. Effects of changes in the fabrication process on the performance of fabricated ICEs are minimized by monitoring the ICE fabrication. For instance, the foregoing process changes can be detected and corrected or prevented altogether by in-situ monitoring the ICE fabrication.

Conventionally, in-situ ellipsometry, optical monitoring or spectroscopy for monitoring the ICE fabrication is performed on one or more witness samples—which are moving with the ICEs along the direction of motion and are located at a single lateral distance relative the direction of motion along a direction orthogonal to the direction of motion—to measure characteristics of probe-light that interacted with the witness sample(s). The witness sample(s) can include one or more of the ICEs being fabricated. The measured characteristics are used next to determine characteristics of deposited layers of the ICEs, e.g., their respective complex refractive indices and thicknesses. Throughout this specification, determining a complex refractive index n* of a layer means that both the real component Re(n*) and the imaginary component Im(n*) of the complex refractive index are being determined Differences between the determined and target complex refractive indices and thicknesses of the formed layers are used to obtain new target complex refractive indices and/or thicknesses for the layers that remain to be deposited. The foregoing steps of such conventional in-situ measurements and optimizations are repeated after deposition of each of the layers of the ICEs being fabricated.

In accordance with technologies disclosed herein, the in-situ monitoring is performed on one or more witness samples—which are moving with the ICEs along the direction of motion and are located at respective lateral distances relative the direction of motion along the orthogonal direction—to measure characteristics of probe-light that interacted with the witness samples. Note that probe-light represents any type of electromagnetic radiation having one or more probe wavelengths from an appropriate region of the electromagnetic spectrum. Results of this spatially-resolved monitoring are used to determine complex refractive indices and thicknesses of layers of the witness samples as a function of the witness samples' lateral distances relative to the direction of motion. As such, actual non-uniformities of the complex refractive indices and thicknesses caused by non-uniformity in the spatial profile of the deposition plume along the orthogonal direction are determined. The complex refractive indices and thicknesses of the formed layers—which can be accurately determined as a function of the witness samples' lateral distances relative to the direction of motion—are used during ICE fabrication to provide feedback for adjusting the ICE fabrication in real-time or near real-time. In this manner, the systems and techniques described herein can provide consistent batch-to-batch yields, and/or improvement of batch yield for the ICE fabrication.

Details of one or more of the foregoing embodiments are described below.

### (3.1) System for ICE Fabrication that Uses Spatially-Resolved Measurements for In-Situ Monitoring the ICE Fabrication

A target ICE design can be provided to an ICE fabrication system in which one or more ICEs are fabricated based on the target ICE design. Technologies for in-situ adjusting ICE fabrication based on results of spatially-resolved measurements are disclosed below. A fabrication system for implementing these technologies is described first.

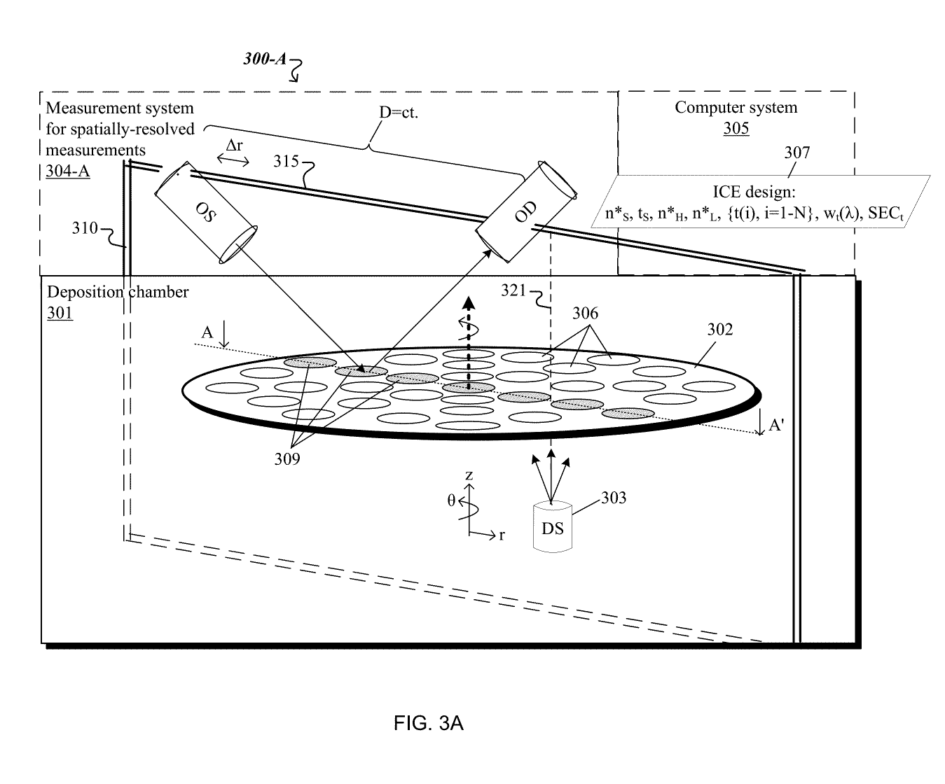

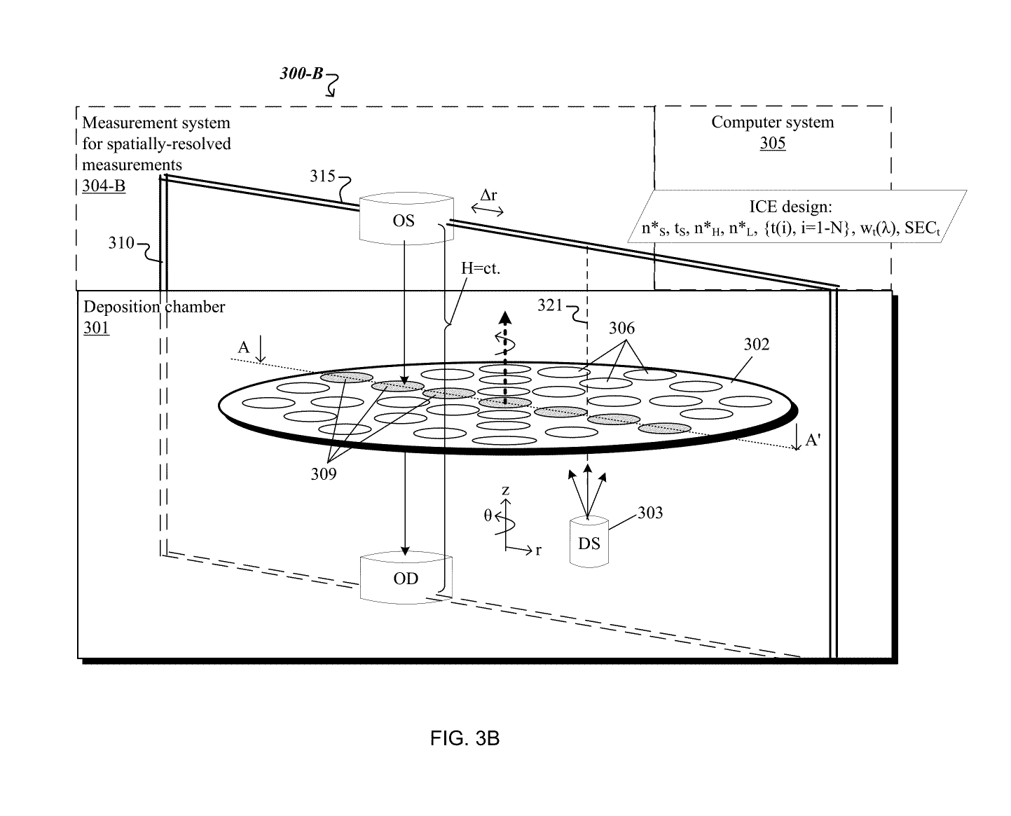

FIGS. 3A-3B show different configurations of an example of an ICE fabrication system 300. The ICE fabrication system 300 includes a deposition chamber 301 to fabricate one or more ICEs 306, a measurement system 304 to measure characteristics of probe-light that interacted with formed layers of the ICEs while the ICEs are being fabricated, and a computer system 305 to control the fabrication of the ICEs 306 based at least in part on results of the measurements. A configuration 300-A of the ICE fabrication system includes a reflectance configuration 304-A of the measurement system, while another configuration 300-B of the ICE fabrication system includes a transmittance configuration 304-B of the measurement system, as described in detail below.

The deposition chamber 301 includes one or more deposition sources 303 to provide materials with low complex index of refraction n*_{L} and high complex index of refraction n*_{H} used to form layers of the ICEs 306. Here, the deposition sources(s) 303 is(are) at rest relative to the deposition chamber 301. Substrates on which layers of the ICEs 306 will be deposited are placed on a substrate support 302, such that the ICEs 306 are within the field of view of the deposition source(s) 303. The substrates have a thickness ts and a complex refraction index n*_{S} specified by a target ICE design 307 (e.g., 145 or 245 described above in connection with FIG. 1A or 2, for instance.) Various physical vapor deposition (PVD) techniques can be used to form a stack of layers of each of the ICEs 306 in accordance with the target ICE design 307.

In accordance with PVD techniques, the layers of the ICE(s) are formed by condensation of a vaporized form of material(s) of the source(s) 305, while maintaining vacuum in the deposition chamber 301. One such example of PVD technique is electron beam (E-beam) deposition, in which a beam of high energy electrons is electromagnetically focused onto material(s) of the deposition source(s) 303, e.g., either Si, or SiO₂, to evaporate atomic species. In some cases, E-beam deposition is assisted by ions, provided by ion-sources (not shown in FIGS. 3A-3B), to clean or etch the ICE substrate(s); and/or to increase the energies of the evaporated material(s), such that they are deposited onto the substrates more densely, for instance. Other examples of PVD techniques that can be used to form the stack of layers of each of the ICEs 306 are cathodic arc deposition, in which an electric arc discharged at the material(s) of the deposition source(s) 303 blasts away some into ionized vapor to be deposited onto the ICEs 306 being formed; evaporative deposition, in which material(s) included in the deposition source(s) 303 is(are) heated to a high vapor pressure by electrically resistive heating; pulsed laser deposition, in which a laser ablates material(s) from the deposition source(s) 303 into a vapor; or sputter deposition, in which a glow plasma discharge (usually localized around the deposition source(s) 303 by a magnet—not shown in FIGS. 3A-3B) bombards the material(s) of the source(s) 303 sputtering some away as a vapor for subsequent deposition.

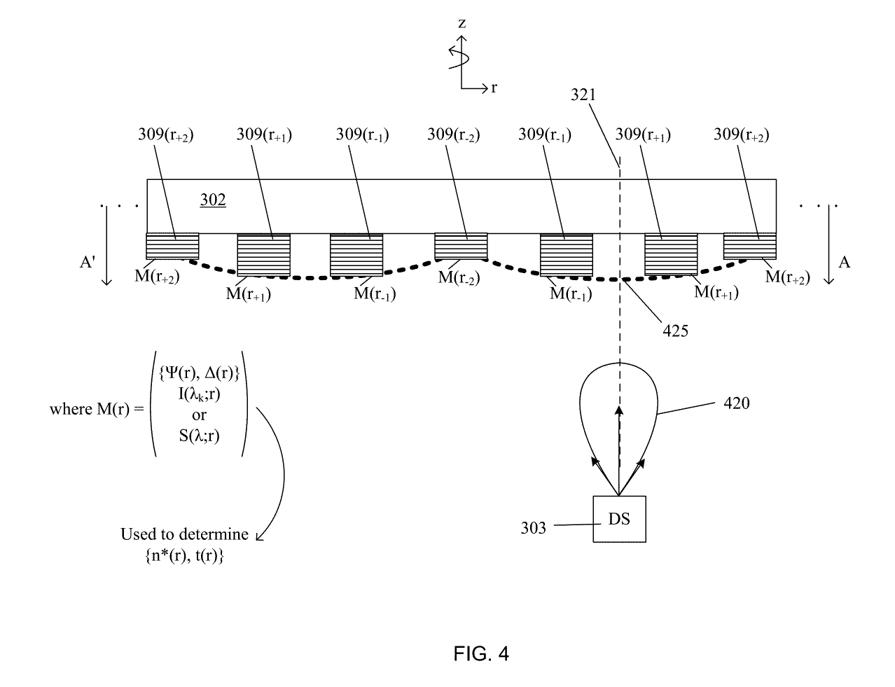

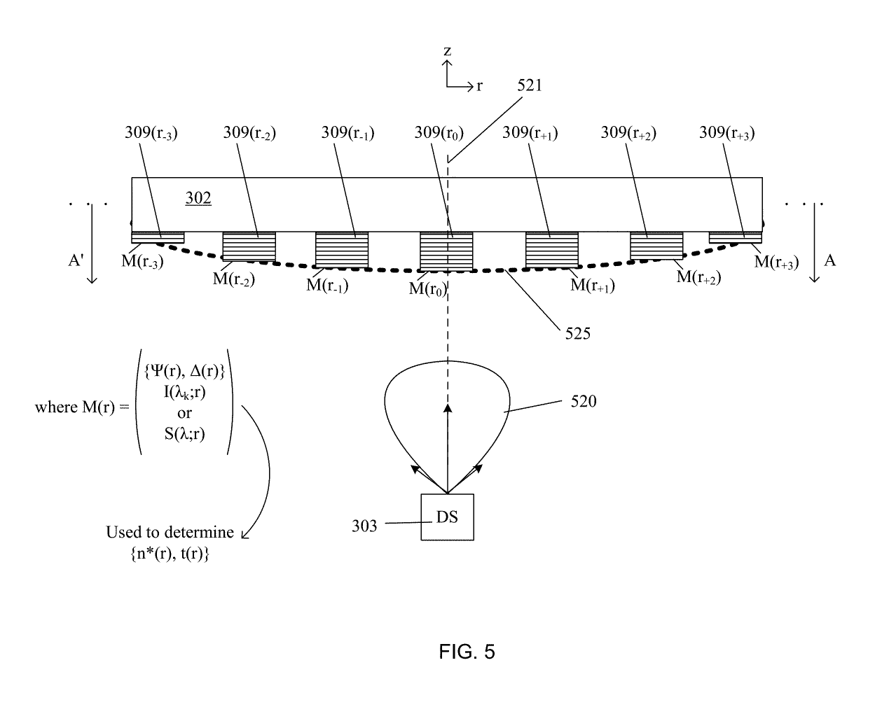

Power provided to the deposition source 303 and its arrangement relative to the current instances of ICEs 306, etc., can be controlled to obtain a specified deposition rate R. For instance, if an ICE design 307 specifies that a j^{th} layer L(j) of the N layers of an ICE is a Si layer with a target thickness t(j), a stack including the previously formed ICE layers L(1), L(2), . . . , L(j−1) is exposed to a Si source—from among the deposition sources 303—for a duration ΔT(j)=t(j)/R_{Si}, where R_{Si} is a deposition rate of the Si source. In the examples illustrated in FIGS. 3A-3B and 4, the deposition source 303 is located on one side of the substrate support 302 at a distance equal to about half a radial dimension, R/2, of the substrate support 302 relative to an axis normal to the substrate support that passes through its center. In another example illustrated in FIG. 5, the deposition source 303 is located on one side of the substrate support 302 along the axis normal to the substrate support that passes through its center. Actual complex refractive indices and thicknesses of the 1^{st} 2^{nd}, . . . , (j−1)^{th} and j^{th} formed layers are determined from measurements of characteristics of probe-light that interacted with the formed layers taken by the measurement system 304.

Referring again to FIGS. 3A-3B, the measurement system 304 includes an optical source (OS) to illuminate a witness sample 309 with probe-light and an optical detector (OD) to detect probe-light that interacted with the witness sample 309. Here, the witness sample 309 is being moved relative to the deposition source(s) 303 along with the ICEs 306 being formed in the deposition chamber 301. The measurement system 304 is coupled to one or more frames 310, such that the source OS and the detector OD are kept at rest relative to each other when the measurement system 304 translates—on a translation stage 315—along the direction (e.g., “r”) perpendicular to the direction of motion (e.g., “θ”) of the ICEs 306 being fabricated in the deposition chamber 301. For example, as the measurement system implemented in the reflectance configuration 304-A translates on the translation stage 315 by a distance Δr along the orthogonal direction (e.g., “r”), the relative distance D between the source OS and the detector OD remains constant, D=constant. As another example, as the measurement system implemented in the transmittance configuration 304-B translates on the translation stage 315 by a distance Δr along the orthogonal direction (e.g., “r”), the relative separation H between the source OS and the detector OD remains constant, H=constant. The distance Δr along the translation stage 315 is measured from on origin thereof. In the examples illustrated in FIGS. 3A and 3B, the origin is a location of the translation stage 315 that is closest to the deposition source 303. A deposition source axis 321 passes through the deposition source 303 and through the origin of the translation stage 315.

The formed layers of any one or more of the current instances of the ICEs 306 can be used as a witness sample by the measurement system 304 to monitor ICE layer deposition in the deposition chamber 301. Note that for in-situ reflectivity measurements configured in accordance with FIG. 3A, substrates of the witness samples 309 may be treated (e.g., the substrates' back surface can be roughened or coated) to provide improved reflection with respect to untreated substrates of the other ICEs 306. Moreover, for in-situ transmissivity measurements configured in accordance with FIG. 3B, any one or more of the ICEs 306 (without having differently treated substrates) can be used as the one or more witness samples 309.

In some implementations, the measurement system 304 is an ellipsometer implemented based on configuration 304-A illustrated in FIG. 3A. The ellipsometer is used to measure, e.g., during or after forming the j^{th} layer of the ICEs 306, amplitude and phase components (Ψ(j;r), Δ(j;r)) of elliptically polarized probe-light—provided by a source OS—after reflection from a stack with j layers of a witness sample 309 that is being formed in the deposition chamber 301 at a lateral distance “r” measured along the translation stage 315 from the deposition source axis 321. In this case, the probe-light is provided by the source OS through a probe port of the deposition chamber 301 associated with the ellipsometer, and the reflected light is collected by a detector OD through a detector port of the deposition chamber 301 associated with the ellipsometer. Here, the measured amplitude and phase components (Ψ(j;r), Δ(j;r)) are used by the computer system 305 to determine the (real and imaginary components of) complex refractive indices and thicknesses of each of the formed layers in the stack: n*_{Si}(r), n*_{SiO2}(r), t′(1;r), t′(2;r), . . . , t′(j−1;r), t′(j;r) for the witness sample 309 located at the lateral distance r from the deposition source axis 321. The computer system 305 makes this determination by solving Maxwell's equations for propagating the interacted probe-light through the formed layers of the witness sample 309.

In other implementations, the measurement system 304 is an optical monitor that can be implemented in a reflectance configuration 304-A illustrated in FIG. 3A or in a transmittance configuration 304-B illustrated in FIG. 3B. The optical monitor is used to measure, e.g., during or after forming the j^{th} layer of the ICEs 306, change of intensity I(j;r;λₖ) of a probe-light—provided by a source OS—due to interaction with (e.g., reflection from or transmission through) the stack with j layers of a witness sample 309 that is being formed in the deposition chamber 301 at a lateral distance “r” measured along the translation stage 315 from the deposition source axis 321. Here, the probe-light has one or more “discrete” wavelengths {λₖ, k=1, 2, . . . }. A discrete wavelength 4 includes a center wavelength λₖ within a narrow bandwidth Δλₖ, e.g., ±5 nm or less; two or more wavelengths, λ₁ and λ₂, contained in the probe-light have respective bandwidths Δλ₁ and Δλ₂ that are not overlapping. The source OS can be a continuous wave (CW) laser, for instance. In this case, the source OS provides probe-light through a probe port of the deposition chamber 301 associated with the optical monitor, and a detector OD collects, through a detector port of the deposition chamber 301 associated with the optical monitor, the interacted light with an intensity I(j;r;λₖ). Here, the measured change of intensity I(j;r;λₖ) can be used by the computer system 305 to determine the complex refractive indices and thicknesses of each of the formed layers in the stack: n*_{Si}(r), n*_{SiO2}(r), t′(1;r), t′(2;r), . . . , t′(j−1;r), t′(j;r) for the witness sample 309 located at the lateral distance r from the deposition source axis 321. The computer system 305 makes this determination by solving Maxwell's equations for propagating the interacted probe-light through the formed layers of the witness sample 309.

In some other implementations, the measurement system 304 is a spectrometer that can be implemented in a transmittance configuration 304-B illustrated in FIG. 3B. The spectrometer is used to measure, e.g., during or after forming the j^{th} layer of the ICEs 306, a spectrum S(j;r;λ) of light—provided by a source OS over a broad wavelength range from, λₘᵢₙ to λₘₐₓ—after transmission through the stack with j layers of a witness sample 309 that is being formed in the deposition chamber 301 at a lateral distance “r” measured along the translation stage 315 from the deposition source axis 321. In this case, the broad wavelength range source OS provides light through a probe port of the deposition chamber 301 associated with the spectrometer, and a detector OD collects the transmitted light through a detector port of the deposition chamber 301 associated with the spectrometer. Here, the measured spectrum S(j;r;λ) over the wavelength range from λₘᵢₙ to λₘₐₓ, can be used by the computer system 305 to determine the complex refractive indices and thicknesses of each of the formed layers in the stack: n*_{Si}(r), n*′_{SiO2}(r), t′(1;r), t′(2;r), t′(j−1;r), t′(j;r) for the witness sample 309 located at the lateral distance r from the deposition source axis 321. The computer system 305 makes this determination by solving Maxwell's equations for propagating the interacted probe-light through the formed layers of the witness sample 309.

As a spatial distribution of a deposition plume provided by the PVD source(s) 303 is non-uniform (e.g., the plume can have a 1/r² spherical distribution or a “cosine emission” Lambertian distribution), a relative orientation, separation and motion between the deposition source(s) 303 and the substrate support 302 are configured to provide desired deposition rate(s) and spatial uniformity across the ICEs 306 distributed on the substrate support 302. For instance, the substrate support 302 is periodically moved with respect to the deposition source(s) 303 along a direction of motion (e.g., rotated about the substrate support 302's center axis that is spaced apart relative to deposition source axis 321) to obtain reproducibly uniform layer deposition of those ICEs being fabricated which are distributed along the direction of motion at a fixed lateral distance relative to the deposition source(s) 303 along a direction orthogonal to the direction of motion (e.g., at r=constant along the radial direction “r” of the substrate support 302 that is rotating along the angular direction “θ”.) However, as the spatial distribution of the deposition plume is non-uniform along the orthogonal direction (e.g., the radial direction “r”), ICEs distributed along the direction of motion (e.g., the angular direction “θ”) at a first lateral distance (e.g., r₁) relative to the deposition source(s) 303 have layers deposited to a first set of thicknesses, other ICEs distributed along the direction of motion at a second lateral distance (e.g., r₂) relative to the deposition source(s) 303 that is larger than the first lateral distance (r₂>r₁) have layers deposited to a second set of thicknesses smaller than the thicknesses of the first set, and so on. To determine, in real-time or near real-time, the different sets of thicknesses corresponding to the different lateral distances (r₁, r₂, . . . ) relative to the deposition source(s) 303, the computer system 305 uses results of in-situ measurements of characteristics of probe-light that interacted with witness samples 309 distributed along the direction (e.g., “r”) perpendicular to the direction of motion (e.g., “θ”) of the ICEs 306 being fabricated in the deposition chamber 301.

Here, “k” witness samples 309 (k≧1) are used for each desired non-zero lateral distance (e.g., r₁, r₂, . . . ) relative to the deposition source(s) 303 where measurements will be taken. As such, the “k” witness samples 309 are placed along the orthogonal direction (e.g., “r”) at each of the desired lateral distances (e.g., rⱼ) relative to the deposition source(s) 303. For example if k=1, a single witness sample is placed at a desired lateral distance rⱼ along the “12 o'clock radius” of a circular platen. In the examples illustrated in FIGS. 3A-3B and 4, k=2 such that two witness samples are placed at a desired lateral distance rⱼ, one along the “12 o'clock radius” and the other one along the “6 o'clock radius” of the circular platen 302. In this manner, the measurement system 304 is translated along the translation stage(s) 315 to each of the desired lateral distances (e.g., rⱼ), so the source OS illuminates with probe-light each of the k witness samples—placed at the desired lateral distance (e.g., rⱼ)—and the detector OD collects, k-times per period, the probe-light interacted with the k witness samples. Also, as shown in FIG. 5, an additional witness sample can be placed above the deposition source(s) 303, at a distance r=0 from the deposition source axis 521. In this case, the measurement system 304 is translated along the translation stage(s) 315 “above” the deposition source(s) 303 for the source OS to illuminate the additional witness sample and for the detector OD to collect, over a specified duration, probe-light interacted with the additional witness sample.

FIG. 4 shows thicknesses of witness samples 309(r₋₂), 2x309(r₋₁), 2x309(r₊₁), 2x309(r₊₂) determined from respective measurements M(j;r_{±k}) of characteristics of probe-light interacted with these witness samples placed along a diameter AA′ of the substrate support 302 at respective locations r_{±k}—where k=1, 2—relative to the deposition source axis 321. Here, the axis 321 intersects the diameter AA′ at a radius equal to about half of the radius of the substrate support 302. The measured characteristics are either (1) amplitude and phase components Ψ(j;r_{±k}), Δ(j;r_{±k}) of an ellipsometer probe-light that reflected from the witness samples 309(r₋₂), 2x309(r₋₁), 2x309(r₊₁), 2x309(r₊₂) placed at respective locations r_{±k} from the deposition source(s) 303, or (2) change of intenisty I(j;λ₁;r_{±k}) of an optical monitor probe-light that interacted with the witness samples 309(r₋₂), 2x309(r₋₁), 2x309(r₊₁), 2x309(r₊₂) placed at respective locations r+k from the deposition source(s) 303, or (3) a spectrum S(j;λ;r_{±k}) of a spectrometer probe-light that interacted with the witness samples 309(r₋₂), 2x309(r₋₁), 2x309(r₊₁), 2x309(r₊₂) placed at respective locations r_{±k} from the deposition source(s) 303. A non-uniform spatial distribution 420 of the deposition plume provided by the deposition source(s) 303 causes the deposited layers of the witness samples 2x309(r₊₁) and 2x309(r₋₁) nearest to the deposition source(s) 303 to have larger thicknesses than the deposited layers of the next-to-nearest witness samples 309(r₋₂) and 2x309(r₊₂). Complex refractive indices of the deposited layers of the witness samples 309(r₋₂), 2x309(r₋₁), 2x309(r₊₁), 2x309(r₊₂) also can vary along the direction orthogonal to the direction of motion due to the non-uniformity of the spatial distribution 420 of the deposition plume provided by the deposition source(s) 303.

In the limiting case when k→∞, a single “platen-size witness sample” is used. Such a platen-size witness sample covers the entire substrate support 302 and rotates about an azimuthal axis passing through its center. In this case, the measurement system 304 is translated continuously along the translation stage(s) 515, starting from above the center of the platen-size witness sample, continuing over the deposition source(s) 303 and ending at the edge of the platen-size witness sample, while the detector OD continuously collects the light interacted with the platen-size witness sample along a spiral path that is continuously illuminated by the source OS. Here, a continuous thickness profile 425 along the AA′ diameter of the platen-size witness sample is determined based on results of the continuous measurements acquired in-situ along the spiral path. As it was in the case of the (2k+1) discrete witness samples described above, the thickness profile 425 along the AA′ diameter of the platen-size witness sample also is non-uniform, in conformance with the non-uniformity of the spatial distribution 420 of the deposition plume provided by the deposition source(s) 303 and its position relative to the center of the platen-size witness sample.

FIG. 5 shows thicknesses of witness samples 309(r₋₃), 309(r₋₂), 309(r₋₁), 309(r₀), 309(r₊₁), 309(r₊₂), 309(r₊₃) determined from respective measurements M(r_{±k}) of characteristics of probe-light interacted with these witness samples placed along a diameter AA′ of the substrate support 302 at respective locations r_{±k}—where k=0, 1, 2, 3—relative to a deposition source axis 521. Here, the axis 521 intersects the diameter AA′ at the center of the substrate support 302. The latter can—but need not—be rotated about its center axis. The measured characteristics are the same as the ones shown in FIG. 4. A non-uniform spatial distribution 520 of the deposition plume provided by the deposition source(s) 303 causes the deposited layers of the “central” witness samples 309(r₀), 309(r₊₁), 309(r₋₁) to have larger thicknesses than the deposited layers of the “fringe” witness samples 309(r₊₂), 309(r₋₂), 309(r₊₃), 309(r₋₃). In analogy with the example shown in FIG. 4, a single “platen-size witness sample” that covers the entire substrate support 302 can be placed above the deposition source(s) 303, where it can—but need not—rotate about an axis that passes through its center. In this case, the measurement system 304 is translated continuously along the translation stage(s) 315, starting from above the deposition source(s) 303 and ending at the edge of the platen-size witness sample, while the detector OD continuously collects the light interacted with the platen-size witness sample along a path (that is spiral when the substrate support 302 rotates about its center axis, or straight when the substrate support 302 is at rest) that is continuously illuminated by the source OS. Once again, a continuous thickness profile 525 along the AA′ diameter of the platen-sized witness sample is determined based on results of the continuous measurements acquired in-situ along the spiral path. As it was in the case of the discrete witness samples 309(r₋₃), 309(r₋₂), 309(r₋₁), 309(r₀), 309(r₊₁), 309(r₊₂), 309(r₊₃) described above, the thickness profile 525 along the AA′ diameter of the plate-sized witness sample also is non-uniform, in conformance with the non-uniformity of the spatial distribution 520 of the deposition plume provided by the deposition source(s) 303.

In some of the implementations shown in FIGS. 3A-3B, 4 and 5, each of the witness samples 309—located along the direction of motion at a fixed lateral distance “r” from the deposition source axis 321—is at rest with respect to the measurement system 304 when the characteristics of the interacted probe-light are measured. Here, deposition of a layer L(j) is interrupted or completed prior to performing the measurement. For some of the layers of an ICE design, the measurement system 304 measures in-situ the characteristics of interacted probe-light after the layer L(j) has been deposited to its full target thickness t(j), or equivalently, when deposition of the layer L(j) is completed. For some of the layers of the ICE design, the measurement system 304 measures the characteristics of the interacted probe-light during the deposition of the layer L(j). For example, such a measurement can be taken when the layer L(j) has been deposited to a fraction of its target thickness f*t(j), e.g., where f=50%, 80%, 90%, 95%, etc.

In other implementations shown in FIGS. 3A-3B, 4 and 5, the witness samples 309—located along the direction of motion at a fixed lateral distance “r” from the deposition source axis 321—are moving with respect to the measurement system 304, e.g., rotate about an azimuthal axis of the substrate support 302 along with the other ICEs 306, when the characteristics of the interacted probe-light are measured. Here, deposition of the layer L(j) may—but need not be—interrupted or completed prior to performing the measurement. For some of the layers of the ICE design, measurements of characteristics of the interacted probe-light can be taken continuously for the entire duration ΔT(j) of the deposition of the layer L(j), or at least for portions thereof, e.g., last 50%, 20%, 10% of the entire duration ΔT(j). In these implementations, a signal of interest (e.g., probe-light polarization modified by reflection off the witness samples 309 for ellipsometry; change of intensity of probe-light transmitted through the witness samples 309 of optical monitoring; or probe-light spectrum modified by transmission through the witness samples 309 for spectroscopy) is collected by the detector OD during the time when each of the moving witness samples 309—located along the direction of motion at a fixed lateral distance “r” from the deposition source axis 321—is illuminated by the probe-light. For example, in cases when the movement of a single witness sample 309—located along the direction of motion at a fixed lateral distance “r” from the deposition source axis 321—is periodic, the signal of interest is averaged over a number of periods of the periodic motion, for instance over 5 periods. As another example, a number k≧2 of witness samples 309—located along the direction of motion at a fixed lateral distance “r” from the deposition source axis 321—can be successively illuminated by the probe-light over each period of the periodic motion. Here, the signal of interest is averaged over the k witness samples. Whether for a single witness sample or for multiple witness samples, no signal is collected, by the detector OD for the remainder of a period of the periodic motion, when the probe-light does not illuminate the witness sample(s) 309.

One complication with measurements of near-infrared (NIR) or mid-infrared (MIR) transmission spectra (as shown in the transmittance configuration of the measurement system 304-B in FIG. 3B) is that stray light emanating from any warm (e.g., a blackbody) surface inside the deposition chamber 301 enters the detector OD and interferes with the spectral acquisition. To avoid these complications, the measurement system 304 is implemented as a single-shot (non-scanning) spectrometer to perform fast spectroscopy. Here, the detector OD of the single-shot spectrometer can be a photodiode array or a CCD array. In this case, a transmission spectrum of the formed layers is collected from and averaged over several (or all) of the witness samples 309—located along the direction of motion at a fixed lateral distance “r” from the deposition source axis 321—that are illuminated by the probe-light during a period of the periodic motion of the witness samples 309. In this manner, as the witness samples 309 move periodically at the fixed lateral distance “r” from the deposition source axis 321, a probe-light beam of the spectrometer alternately interacts with a witness sample 309 at the fixed lateral distance “r” from the deposition source axis 321, and then the probe-light beam is blocked by the physical substrate support 302 until the next witness sample 309 at the fixed lateral distance “r” from the deposition source axis 321 enters the probe-light beam. A spectrum corresponding to the formed layers of the witness samples 309—located along the direction of motion at a fixed lateral distance “r” from the deposition source axis 321—is collected by the detector OD when the probe-light beam illuminates each of the witness samples 309—located along the direction of motion at a fixed lateral distance “r” from the deposition source axis 321—and a background spectrum is collected by the detector OD when the probe-light beam illuminates adjacent to (in between) the witness samples and it is physically absorbed or blocked by the substrate support 302 from reaching the detector OD. In addition, at least one reference spectrum (also referred to as a baseline spectrum) is collected during the period of the periodic motion when the probe-light beam passes through an aperture of the substrate support 302 without passing through a witness sample 309 and without being blocked by the substrate support 302. The reference spectrum is used to subtract (or normalize) temporal and/or spectral variations of the probe-light from the spectrum associated with the deposited layers. Moreover, the background spectrum can be used to compensate (or zero out) much of spectral contributions of the stray light from the reference spectrum and from the spectrum associated with the deposited layers. The foregoing allows for accurate baseline and background corrections and thus enables recording of an accurate spectrum associated with the deposited layers of the ICEs 306.

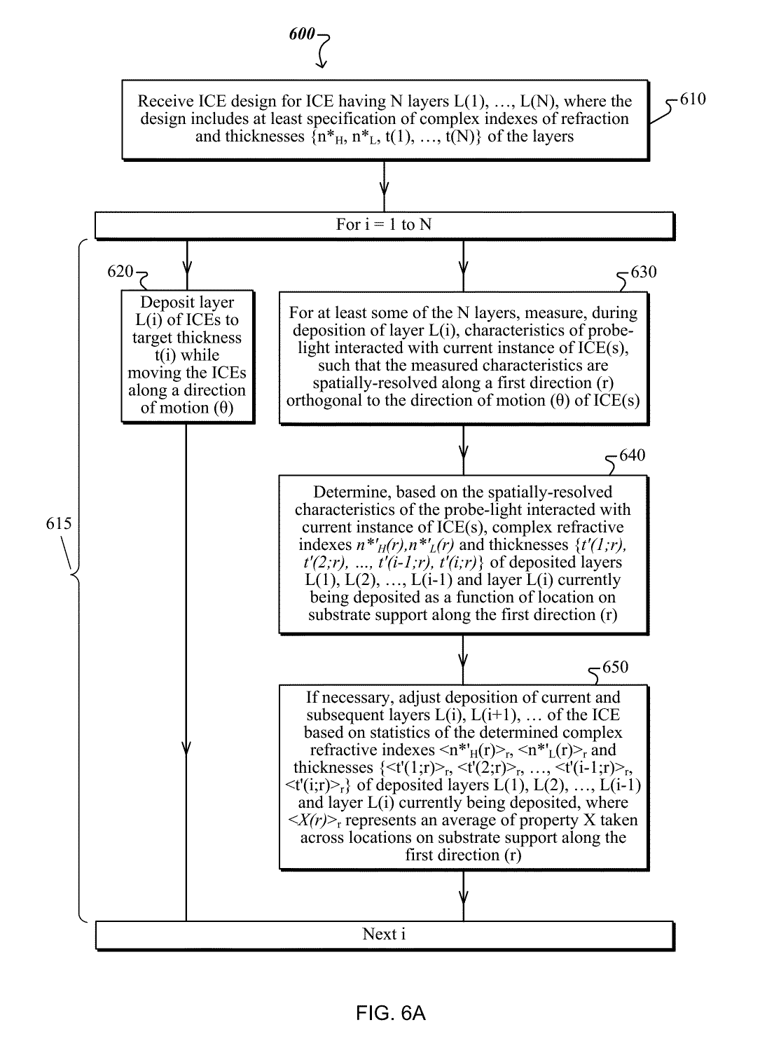

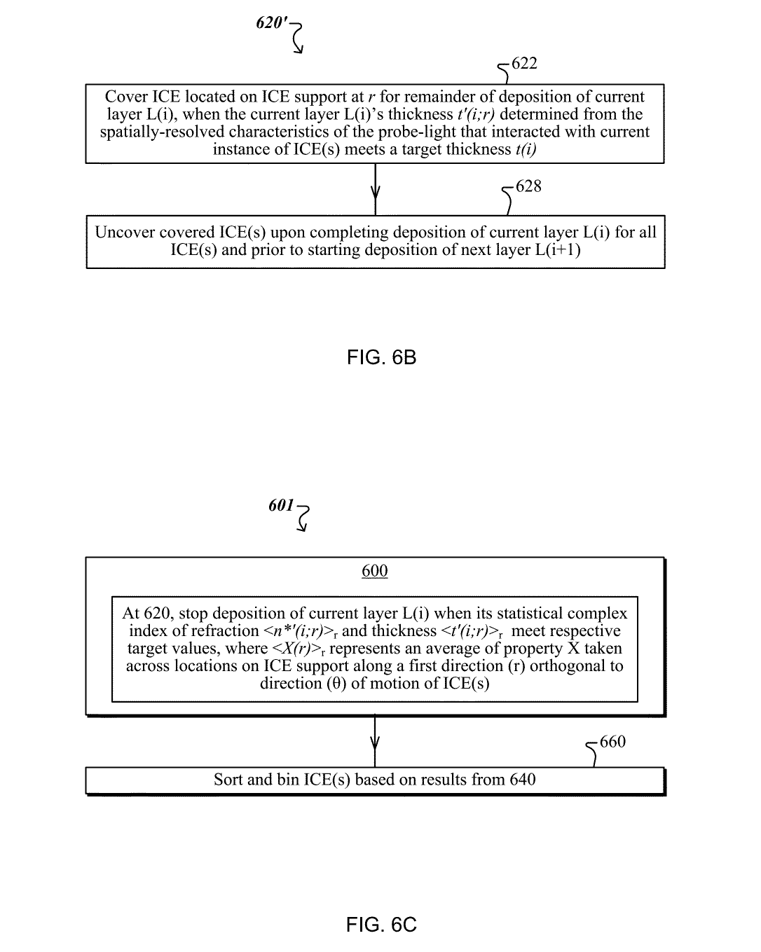

The computer system 305 includes one or more hardware processors and memory. The memory encodes instructions that, when executed by the one or more hardware processors, cause the fabrication system 300 to perform processes for fabricating the ICEs 306. Examples of such processes are described below in connection with FIGS. 6A-6C. The computer system 305 also includes or is communicatively coupled with a storage system that stores one or more ICE designs 307, aspects of the deposition capability, and other information. The stored ICE designs can be organized in design libraries by a variety of criteria, such as ICE designs used to fabricate ICEs for determining values of a particular characteristic over many substances (e.g. the GOR ratio in crude oil, refined hydrocarbons, mud, etc.), or ICE designs used to fabricate ICEs for determining values of many properties of a given substance (e.g., viscosity, GOR, density, etc., of crude oil.) In this manner, upon receipt of an instruction to fabricate an ICE for measuring a given characteristic of a substance, the computer system 305 accesses such a design library and retrieves an appropriate ICE design 307 that is associated with the given characteristic of the substance.

The retrieved ICE design 307 includes specification of a substrate and a total number N of layers to be formed in the deposition chamber 301 on the substrate; specification of a complex refractive index n*_{S} of a material of the substrate, a high complex refractive index n*_{H} and a low complex refractive index n*_{L} of materials (e.g., Si and SiO₂) to form the N layers with adjacent layers having different complex refractive indices; and specification of target thicknesses {ts, t(k), k=1−N} of the substrate and the N layers. Implicitly or explicitly, the ICE design 307 also can include specification of a target optical spectrum wₜ(λ) associated with the given characteristic; and specification of a target SECₜ representing expected performance of an ICE associated with the retrieved ICE design 307. The foregoing items of the retrieved ICE design 307 were determined, prior to fabricating the ICEs 306, in accordance with the ICE design process 200 described above in connection with FIG. 2. In some implementations, the ICE design 307 can include indication of maximum allowed SECₘₐₓ caused by fabrication errors. Figures of merit other than the target SECₜ can be included in the retrieved ICE design 307, e.g., SEP, the ICE sensitivity, etc.

The complex refractive indices and target thicknesses {t(k), k=1−N} of the N layers, as specified by the retrieved ICE design 307, are used by the computer system 305, in conjunction with aspects of deposition capability of the ICE fabrication system 300, to control deposition rate(s) of the deposition source(s) 303 and respective deposition times for forming the ICE layers. While forming the ICE layers, the computer system 305 instructs the measurement system 304 associated with the ICE fabrication system 300 to measure characteristics of probe-light that interacted with formed layers of ICEs being fabricated by performing spatially-resolved in-situ measurements. The measured characteristics of the probe-light that interacted with the formed layers of the ICEs are used by the computer system 305 to determine complex refractive indices and thicknesses of the formed layers as a function of the ICEs' locations relative to the deposition source(s) 303. Then, the computer system 305 can instruct the ICE fabrication system 300 to complete the forming of the current layer—in some cases on an ICE-by-ICE basis—upon determining that its thickness target has been reached. If necessary, the computer system 305 also instructs the ICE fabrication system 300 to adjust the forming of layers remaining to be formed based on the determined complex refractive indices and thicknesses of the formed layers of the ICEs.

### (3.2) Adjusting of ICE Fabrication Based on Results of Spatially-Resolved Measurement Techniques

FIG. 6A is a flow chart of an example of an ICE fabrication process 600 for fabricating ICEs that uses spatially-resolved measurement techniques for in-situ monitoring of the ICE fabrication. The process 600 can be implemented in conjunction with the ICE fabrication system 300 to adjust ICE fabrication. In such a context, the process 600 can be implemented as instructions encoded in the memory of the computer system 305, such that execution of the instructions, by the one or more hardware processors of the computer system 305, causes the ICE fabrication system 300 to perform the following operations.

At 610, an ICE design is received. The received ICE design includes specification of a substrate and N layers L(1), L(2), . . . , L(N), each having a different complex refractive index from its adjacent layers, and specification of target complex refractive indices and thicknesses ts, t(1), t(2), . . . , t(N). In this manner, an ICE fabricated in accordance with the received ICE design selectively weights, when operated, light in at least a portion of a wavelength range by differing amounts. The differing amounts weighted over the wavelength range correspond to a target optical spectrum wₜ(λ) of the ICE and are related to a characteristic of a sample. For example, a design process for determining the specified (1) substrate and number N of layers of the ICE, each having a different complex refractive index from its adjacent layers, and (2) complex refractive indices and thicknesses of the substrate and the N layers that correspond to the target optical spectrum wₜ(λ) of the ICE is described above in connection with FIG. 2. In some implementations, the received ICE design also can include SECₜ as an indication of a target performance of the ICE. The target performance represents an accuracy with which the ICE predicts, when operated, known values of the characteristic corresponding to validation spectra of the sample. Here, predicted values of the characteristic are obtained when the validation spectra weighted by the ICE are respectively integrated. In some implementations, the received ICE design also can include indication of maximum allowed SECₘₐₓ caused by fabrication errors.

Loop 615 is used to fabricate one or more ICEs based on the received ICE design. Each iteration “i” of the loop 615 is used to form a layer L(i) of a total number N of layers. Here, the total number N of layers can be either specified in the received ICE design or updated during the ICE fabrication. Updates to the received ICE design are performed when necessary for preventing performance of the fabricated ICE to degrade under a threshold value.

At 620, an i^{th} layer L(i) of the total number N of layers is formed to a target thickness t(i) while moving a plurality of ICEs being fabricated along a direction of motion. The target thickness t(i) of the layer L(i) can be specified by the received ICE design or updated based on optimization(s) carried out after forming previous one or more of the layers of the ICEs. Characteristics of the motion—e.g., distance and orientation of the direction of motion relative to the deposition source(s) 303, whether the motion is periodic, and if so its period—are configured to mitigate deposition non-uniformities among the plurality of ICEs within a fabrication batch, the non-uniformities being caused by a non-uniform spatial profile of a deposition plume provided by the deposition source(s) 303. In the examples shown in FIGS. 3A-3B and 4, the ICEs are placed on a substrate support 302 that rotates about a rotation axis that passes through its center. Here, the rotation axis of the substrate support 302 is placed apart from the deposition source axis 321. In the example shown in FIG. 5, the ICEs are placed on a substrate support 302 that rotates about a rotation axis that passes through its center and coincides with the deposition source axis 521.

For some of the layers of the ICE, a deposition source having a deposition rate R is used for a total time duration ΔT(i)=t(i)/R to deposit the layer L(i) to its target thickness as part of a single deposition step. Other layers are deposited to the target thickness t(i) using multiple deposition steps by discretely or continuously forming respective sub-layers of the layer L(i). Here, the deposition rate used for depositing each of the sub-layers can be the same or different from each other. In the case when the deposition rates for forming the sub-layers are different, the last few sub-layers of the layer L(i) can be formed using slower rates than the ones used for forming the first few sub-layers of the layer L(i).

At 630, while the layer L(i) is being formed, spatially-resolved, in-situ optical measurements are performed to determine changes in characteristics of a probe-light due to its interaction with the layer currently being formed and the previously formed layers. The measured characteristics are spatially-resolved along a first direction (e.g., r) orthogonal to the direction of motion (e.g., θ) of the ICEs being fabricated. In the examples illustrated in FIGS. 3A-3B, spatially-resolved optical measurements performed using the measurement system 304 include at least one of (1) in-situ ellipsometry to measure amplitude and phase components {Ψ(i;r),Δ(i;r)} of probe-light interacted with a current instance of a subset of the ICE(s) disposed at a lateral distance r from the deposition source axis 321, (2) in-situ optical monitoring to measure change of intensity I(i;r;λₖ) of probe-light interacted with the current instance of the subset of ICE(s) disposed at the lateral distance r from the deposition source axis 321, and (3) in-situ spectroscopy to measure a spectrum S(i;r;λ) of probe-light interacted with the current instance of the subset of ICE(s) disposed at the lateral distance r from the deposition source axis 321.

For some of the layers of the received ICE design, the spatially-resolved optical measurements can be skipped altogether. In this case, either no optical measurements are taken, or optical measurements are taken at a single location relative to the deposition source(s) 303 (in a non-spatially-resolved manner.) For some other layers, the spatially-resolved optical measurements are carried out continuously during the deposition of a layer L(i), in some implementations. In other implementations, the spatially-resolved optical measurements are taken a finite number of times during the deposition of the layer L(i). In the latter case, the finite number of times can represent times when at least some of the sub-layers of the layer L(i) are completed.

At 640, complex refractive indices n*′_{H}(r) and n*′_{L}(r) and thicknesses t′(1;r), t′(2;r), . . . , t′(i−1;r), t′(i;r) of the layers L(1), L(2), . . . , L(i−1) formed in previous iterations of the loop 615 and the layer L(i) that is currently being formed are determined in real-time (or near real-time) as a function of the lateral distance (e.g., “r”) to the deposition source along the direction orthogonal to the direction of motion (e.g., “0”) of the ICEs. In this manner, thickness profiles, e.g., 425 in FIG. 4 or 525 in FIG. 5, can be obtained in real-time (or near real-time) based on the determined thicknesses t′(1;r), t′(2;r), . . . , t′(i−1;r), t′(i;r) to quantify—for the ICEs 306 fabricated in the deposition chamber 301—thickness non-uniformities of the formed layers. The obtained thickness profiles can be used by the computer system 305 for modifying the deposition operation 620 in the following manner.

FIG. 6B illustrates an example of a modification of the deposition, performed at 620, of the i^{th} layer L(i) to a target thickness t(i). This modification can be implemented in the ICE fabrication system 300 described above in connection with FIGS. 3A-3B. Here, an ICE located on the substrate support 302 at a lateral distance “r” from the deposition source(s) 303 is covered, when the current layer L(i)'s thickness t′(i;r) determined from the measured spatially-resolved characteristics of the interacted probe-light, e.g., at least one of {Ψ(i;r),Δ(i;r)}, I(i;λₖ;r) or S(i;λ;r), meet a target thickness t(i). This ICE remains covered until deposition of the current layer L(i) is completed for all ICEs in the batch. In some implementations, a baffle may be provided between the ICEs—for which the determined thickness t′(i;r) of the deposited layer L(i) has met the target thickness t(i)—and the deposition source(s) 303 for covering these ICEs.

For instance, the measurement system 304 is translated on the translation stage 315 at r_{±1}, “above” one or more of the ICEs located on the substrate support 302 nearest to the deposition source axis 321, such that probe-light provided by the source OS illuminates the nearest ICE(s). At r_{±1}, the measurement system 304 measures characteristics of the probe-light that interacted with the nearest ICE(s), and the computer system 305 uses the measured characteristics to determine in real-time a thickness t′(i;r_{±1}) of the current layer L(i) for the nearest ICE(s). When the determined thickness t′(i;r_{±1}) of the current layer L(i) of the nearest ICE(s) meets the target thickness t(i), the nearest ICE(s) is(are) covered for the remainder of the deposition of the current layer L(i) of all the remaining ICEs in the batch. Further, the measurement system 304 is translated along the translation stage 315 to a radius r_{±2}, above one or more ICEs that are next-to-nearest to the deposition source axis 321, such that probe-light provided by the source OS illuminates the next-to-nearest ICE(s). At r_{±2}, the measurement system 304 measures characteristics of the probe-light that interacted with the next-to-nearest ICE(s), and the computer system 305 uses the measured characteristics to determine in real-time a thickness t′(i;r_{±2}) of the current layer L(i) for the next-to-nearest ICE(s). When the determined thickness t′(i;r_{±2}) of the current layer L(i) of the next-to-nearest ICE(s) meets the target thickness t(i), the next-to-nearest ICE(s) is(are) covered for the remainder of the deposition of the current layer L(i) of all the remaining ICEs in the batch.

In general, at 622, the measurement system 304 is translated along the translation stage 315 to a radius r_{±k}, above one or more ICEs that are k^{th}-to-nearest to the deposition source axis 321, such that probe-light provided by the source OS illuminates the k^{th}-to-nearest ICE(s). At r_{±k}, the measurement system 304 measures characteristics of the probe-light that interacted with the k^{th}-to-nearest ICE(s), and the computer system 305 uses the measured characteristics to determine in real-time a thickness t′(i;r_{±k}) of the current layer L(i) for the k′-to-nearest ICE(s). When the determined thickness t′(i;r_{±k}) of the current layer L(i) of the k^{th}-to-nearest ICE(s) meets the target thickness t(i), the k^{th}-to-nearest ICE(s) is(are) covered for the remainder of the deposition of the current layer L(i) of all the remaining ICEs in the batch. And so on until deposition of the current layer L(i) is completed for all the ICEs in the batch.

At 628, the covered ICEs are uncovered upon completing deposition of the current layer L(i) for all ICEs and prior to starting deposition of next layer L(i+1).

Referring again to FIG. 6A, statistics of the thicknesses t′(1;r), t′(2;r), t′(i−1;r), t′(i;r) determined at 640 for all lateral distances r=r_{±k}, where k=1, 2, . . . , can be obtained. For example, a statistic of the thickness <t′(1;r)>ᵣ of the first formed layer L(1) is taken over a set of determined thicknesses {t′(1;r_{±1}), t′(1;r_{±2}), . . . } of the first formed layer L(1) for the ICEs supported on the substrate support 302 at lateral distances r_{±1}, r_{±2}, . . . from the deposition source axis 321. And so on, statistics of the thicknesses <t′(2;r)>ᵣ, <t′(i−1;r)>ᵣ of the other formed layers L(2), . . . , L(i−1) are obtained in a similar manner. Further, a statistic of the thickness <t′(i;r)>ᵣ of the layer L(i) that is currently being formed is taken over the determined thicknesses {t′(i;r_{±1}), t′(i;r_{±2}), . . . } of the layer L(i) for the ICEs supported on the substrate support 302 at the lateral distances r_{±1}, r_{±2}, . . . . Example of statistics <•(r)>ᵣ that can be obtained here are an average, a truncated average, a median, a maximum or a minimum. For example, an average thickness of the first formed layer L(1) is Mean(t′(1;r_{±1}), t′(1;r_{±2}), . . . ). As another example, a minimum thickness of the first formed layer L(1) is Min(t′(1;r_{±1}), t′(1;r_{±2}), . . . ).

One or more of the obtained statistics can be used to control completion of the deposition of the layer L(i) currently being formed. As such, in some implementations, deposition (at 620) of current layer L(i) is completed when a statistic of the thickness <t′(i;r)>ᵣ of the current layer L(i)—taken over the determined thicknesses {t′(i;r_{±1}), t′(i;r_{±2}), . . . } of the layer L(i) for the ICEs supported on the substrate support 302 at the lateral distances r_{±1}, r_{±2}, . . . —meets a target thickness t(i). Additionally, the obtained statistics can be used to modify deposition of the current layer L(i) and of the subsequent layers L(i+1), L(i+2), . . . as described below.

At 650, deposition of current and subsequent layers L(i), L(i+1), . . . of the ICE(s) being fabricated in the deposition chamber 301 is adjusted, if necessary, based on the obtained statistics of the complex refractive indices <n*′_{H}(r)>ᵣ, <n*′_{L}(r)>ᵣ and thicknesses {<t′(1;r)>ᵣ, <t′(2;r)>ᵣ, <t′(i−1;r)>ᵣ, <t′(i;r)>ᵣ} of deposited layers L(1), L(2), . . . , L(i−1) and layer L(i) currently being deposited. The foregoing statistics are referred to as the statistical complex refractive indices and the statistical thicknesses. For example, a deposition rate used to form the layer L(i) currently being formed and other layers L(i+1), L(i+2), . . . remaining to be formed can be adjusted based on a comparison between the statistical complex refractive indices and thicknesses of the layers of the current instance of the ICEs and their respective target values. Alternatively or additionally, complex refractive indices corresponding to the layer L(i) being current formed and other layers L(i+1), L(i+2), . . . remaining to be formed can be adjusted based on a comparison between the statistical complex refractive indices and thicknesses of the layers of the current instance of the ICEs and their respective target values.

Further, in order to determine whether target thicknesses of the layer L(i) being current formed and other layers L(i+1), L(i+2), . . . , L(N) remaining to be formed should be updated, the following verification is performed. An SEC(i) of the ICE is predicted to represent an ICE's performance if the ICE were completed to have the formed layers L(1), L(2), . . . , L(i−1) with the statistical thicknesses <t′(1;r)>ᵣ, <t′(2;r)>ᵣ, . . . , <t′(i−1;r)>ᵣ, and the layer L(i) currently being formed and other layers L(i+1), L(i+2), . . . , L(N) remaining to be formed with target thicknesses t(i), t(i), . . . , t(N). Here, the predicted SEC(i) is caused by deviations of the statistical complex refractive indices and thicknesses of the formed layers from their respective complex refractive indices and target thicknesses specified by the current ICE design. If the predicted SEC(i) does not exceed the maximum allowed SECₘₐₓ, SEC(i)≦SECₘₐₓ, then the forming of the current layer L(i) is completed in accordance to its target thickness t(i) and a next iteration of the loop 415 will be triggered to form the next layer L(i+1) to its target thickness t(+1).

If, however, the predicted SEC(i;N) exceeds the maximum allowed SECₘₐₓ, SEC(i;N)>SECₘₐₓ, then target thicknesses of the layer L(i) currently being formed and other layers L(i+1), L(i+2), . . . , L(N) remaining to be formed are modified based on the statistical complex refractive indices and thicknesses of the formed layers L(1), L(2), . . . , L(i). This optimization may change the total number of layers of the ICE from the specified total number N of layers to a new total number N′ of layers, but constrains the thicknesses of the layers L(1), L(2), . . . , L(i) (of the current instance of the ICE) to the statistical thicknesses <t′(1;r)>ᵣ, <t′(2;r)>ᵣ, . . . , <t′(i−1;r)>ᵣ. In this manner, the optimization obtains, in analogy with the process 200 described above in connection with FIG. 2, new target thicknesses t″(i), t″(i+1), . . . , t″(N′) of the layer L(i) currently being formed and other layers L(i+1), . . . , L(N′) remaining to be formed, such that a new target SEC′ₜ(i;N′) of the ICE—for the ICE having the first layers L(1), L(2), . . . , L(i−1) formed with the statistical thicknesses <t″(1;r)>ᵣ, <t′(2;r)>ᵣ, . . . , <t′(i−1;r)>ᵣ, and the layer L(i) currently being formed and other layers L(i+1), . . . , L(N′) remaining to be formed with the new target thicknesses t″(i), t″(i+1), . . . , t″(N′)—is minimum and does not exceed the maximum allowed SECₘₐₓ, SEC′ₜ(i;N′)≦SECₘₐₓ.

Once the previous instance of the ICE design is updated with specification of the new total number of layers N′ and the new target thicknesses t″(i), t″(i+1), . . . , t″(N′)—which are used to form the current layer L(i) and the remaining layers L(i+1), . . . , L(N′) and correspond to the new target SEC′ₜ(i;N′)—the forming of the current layer L(i) is completed in accordance with its new target thickness t″(i) and a next iteration of the loop 615 will be triggered to form the next layer L(i+1) from the new total number of layers N′ to its new target thickness t″(i+1). In this manner, the remaining layers of the ICE will be formed based on the updated ICE design, at least until another update is performed.

Other modifications and/or extensions of the process 600 can be implemented based on the thickness profiles obtained at 640.

FIG. 6C is a flowchart of an example of an ICE fabrication process 601 which is a modification and an extension of the process 600. Here, at 620, deposition of the current layer L(i) of the ICEs being fabricated is completed when it's statistical complex index of refraction <n*′(i;r)>ᵣ and thickness <t′(i;r)>ᵣ meet respective target values. The statistical complex index of refraction <n*′(i;r)>ᵣ and thickness <t′(i;r)>ᵣ of the layer L(i) currently being deposited are obtained, at 640, as described above in connection with FIG. 6A. Moreover, except for the foregoing modifications of the deposition 620, the ICE fabrication can be carried out in accordance with the process 600.

At 660, once fabrication of ICEs of the current batch is completed, the fabricated ICEs are sorted and binned based on their spatially-resolved thicknesses determined at 640. For instance, the N layers of a first set of ICEs located at a lateral distance r_{±1} from the deposition source axis 321 were fabricated with thicknesses {t′(1;r_{±1}), t′(2;r_{±1}), . . . , t′(N;r_{±1})}. As such, the ICEs of the first set have a corresponding optical spectrum w(λ;r_{±1}) different from the target optical spectrum wₜ(λ) and a predicted SEC(r_{±1}) from the target performance corresponding to differences between the optical spectrum w(λ;r_{±1}) and the target optical spectrum wₜ(λ). Further, the N layers of a second set of ICEs located at a lateral distance r_{±2} from the deposition source axis 321 were fabricated with thicknesses {t′(1;r_{±2}), t′(2;r_{±2}), . . . , t′(N;r_{±2})}. As such, the ICEs of the second set have a corresponding optical spectrum w(λ;r_{±2}) different from the target optical spectrum wₜ(λ) and a predicted SEC(r_{±2}) from the target performance corresponding to differences between the optical spectrum w(λ;r_{±2}) and the target optical spectrum wₜ(λ). In general, the N layers of a k^{th} set of ICEs located at a lateral distance r_{±k} from the deposition source axis 321 were fabricated with thicknesses {t′(1;r_{±k}), t′(2;r_{±k}), t′(N;r_{±k})}. As such, the ICEs of the k^{th} set have a corresponding optical spectrum w(λ;r_{±k}) different from the target optical spectrum wₜ(λ) and a predicted SEC(r_{±k}) from the target performance corresponding to differences between the optical spectrum w(λ;r_{±k}) and the target optical spectrum wₜ(λ).

In this manner, the foregoing sets of ICEs can be ranked based on the predicted SEC, such that the p^{th} set of ICEs with the smallest degradation from the target performance SEC(r_{±p}) is considered to be the most performing set, and the q^{th} set of ICEs with the largest degradation from the target performance SEC(r_{±q}) is considered to be the least performing set. Moreover, the sets of ICEs for which corresponding degradation from the target performance (expressed in terms of SEC(r)) exceeds the maximum allowed SECₘₐₓ can be discarded.

Some embodiments have been described in detail above, and various modifications are possible. While this specification contains many specifics, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments.

Other embodiments fall within the scope of the following claims.

1. A method comprising:
receiving, by a fabrication system, a design of an integrated computational element (ICE), the ICE design comprising specification of a substrate and a plurality of layers, their respective target thicknesses and complex refractive indices, wherein complex refractive indices of adjacent layers are different from each other, and wherein a notional ICE fabricated in accordance with the ICE design is related to a characteristic of a sample;
forming, by the fabrication system, at least some of the layers of a plurality of ICEs in accordance with the ICE design, wherein the layers of the ICEs are supported on a support that is being moved during said forming along a direction of motion;
in-situ measuring, by a measurement system associated with the fabrication system, characteristics of probe-light that interacts with formed layers of the ICEs such that the measured characteristics are spatially-resolved along a first direction orthogonal to the direction of motion;
determining, by the fabrication system based on the spatially-resolved characteristics of the probe-light that interacted with the formed layers of the ICEs, complex refractive indices or thicknesses of the formed layers of the ICEs as a function of the ICEs' location on the support along the first direction; and
adjusting, by the fabrication system, said forming, at least in part, based on the determined complex refractive indices and thicknesses.

2. The method of claim 1, further comprising obtaining a statistic along the first direction for each of the determined complex refractive indices and thicknesses of the formed layers of ICEs distributed on the support along the first direction.

3. The method of claim 2, wherein the statistic is selected from a group consisting of an average, a truncated average, a median, a maximum and a minimum.

4. The method of claim 2, wherein said adjusting of said forming is performed using the obtained statistic along the first direction of the determined complex refractive indices and thicknesses of the formed layers.

5. The method of claim 2, further comprising:
completing, by the fabrication system for each layer of the plurality of layers, deposition of the layer when the statistic along the first direction of thicknesses of the layer satisfies a target thickness, and
automatically sorting and binning, by the fabrication system, the plurality of ICEs based on results of said determining.

6. The method of claim 1, further comprising, for each layer of the plurality of layers:
covering, by the fabrication system for the remainder of forming of the layer, ICEs located on the support at a particular location along the first direction, when a thickness of the layer determined from the in-situ measured characteristics at the particular location satisfies an associated target thickness, and
uncovering, by the fabrication system, the covered ICEs upon completing the deposition of the layer and prior to starting deposition of the next layer.

7. The method of claim 1, wherein said measuring the characteristics of the probe-light that interacts with the formed layers of the ICEs is performed by detecting the interacted probe-light while scanning a beam of the probe-light across a dimension of the support along the first direction.

8. The method of claim 7, wherein said detecting the interacted probe-light is performed continuously during said scanning of the probe-light beam over a witness sample moving with the ICEs along the direction of motion, where the witness sample spans substantially the entire dimension of the support along the first direction.

9. The method of claim 7, wherein said detecting the interacted probe-light is performed discretely during said scanning of the probe-light beam over multiple witness samples moving with the ICEs along the direction of motion, where the witness samples are distributed over the entire dimension of the support along the first direction.

10. The method of claim 1, wherein
the support is a platen,
the direction of motion is an azimuthal direction associated with a rotation of the platen around its center, and
the first direction is a radial direction of the platen.

11. The method of claim 1, wherein a deposition plume provided by a deposition source used for said forming is non-uniform at least along the first direction.

12. The method of claim 11, wherein
a non-uniformity of the deposition plume is symmetric relative to the direction of motion, and
said measuring of the characteristics is performed along the first direction on a single side of the direction of motion.

13. The method of claim 1, wherein
the measurement system associated with the fabrication system comprises an ellipsometer, and
the spatially-resolved characteristics of the probe-light that interacted with the formed layers of the ICEs comprise amplitude and phase components of the interacted probe-light.

14. The method of claim 1, wherein
the measurement system associated with the fabrication system comprises an optical monitor, and
the spatially-resolved characteristics of the probe-light that interacted with the formed layers of the ICEs comprise a change of intensity of the interacted probe-light.

15. The method of claim 1, wherein
the measurement system associated with the fabrication system comprises a spectrometer, and
the spatially-resolved characteristics of the probe-light that interacted with the formed layers of the ICEs comprise a spectrum of the interacted probe-light.

16. The method of claim 1, wherein said adjusting comprises updating a deposition rate used to form the layers remaining to be formed based on the determined complex refractive indices and thicknesses of the formed layers of the ICE.

17. The method of claim 1, wherein said adjusting comprises modifying complex refractive indices of the layers remaining to be formed based on the determined complex refractive indices and thicknesses of the formed layers of the ICE.

18. The method of claim 1, wherein said adjusting comprises modifying target thicknesses of the layers remaining to be formed based on the determined complex refractive indices and thicknesses of the formed layers of the ICE.

19. The method of claim 18, wherein said adjusting comprises changing a total number of layers specified by the ICE design to a new total number of layers.

20. A system comprising:
a deposition chamber;
one or more deposition sources associated with the deposition chamber to provide materials from which layers of one or more integrated computational elements (ICEs) are formed;
one or more supports disposed inside the deposition chamber, at least partially, within a field of view of the one or more deposition sources to support the layers of the ICEs and to move them along a direction of motion while the layers are formed;
a measurement system associated with the deposition chamber to measure one or more characteristics of the layers of the ICEs while the layers are formed, wherein the characteristics are measured as a function of location of the ICEs along a direction orthogonal to the direction of motion; and
a computer system in communication with at least some of the one or more deposition sources, the one or more supports and the measurement system, wherein the computer system comprises one or more hardware processors and non-transitory computer-readable medium encoding instructions that, when executed by the one or more hardware processors, cause the system to form the layers of the ICEs by performing operations comprising:
receiving a design of an integrated computational element (ICE), the ICE design comprising specification of a substrate and a plurality of layers, their respective target thicknesses and complex refractive indices, wherein complex refractive indices of adjacent layers are different from each other, and wherein a notional ICE fabricated in accordance with the ICE design is related to a characteristic of a sample;
forming at least some of the layers of the ICEs in accordance with the ICE design, wherein the layers of the ICEs are supported by the one or more supports that are being moved during said forming along the direction of motion;
in-situ measuring, by the measurement system, characteristics of probe-light that interacts with the formed layers of the ICEs such that the measured characteristics are spatially-resolved along a first direction orthogonal to the direction of motion;
determining, based on the spatially-resolved characteristics of the probe-light that interacted with the formed layers of the ICEs, complex refractive indices or thicknesses of the formed layers of the ICEs as a function of the ICEs' location on at least one of the supports along the first direction; and
adjusting said forming, at least in part, based on the determined complex refractive indices and thicknesses.

21. The system of claim 20, further comprising one or more translation stages to translate the measurement system relative to the direction of motion of the ICEs along the orthogonal direction.

22. The system of claim 21, wherein the measurement system is translated to multiple locations along the orthogonal direction where it is stopped prior to measuring the characteristics of the layers of respective subsets of ICEs supported by the support at each of the multiple locations.

23. The system of claim 21, wherein
a particular one of the ICEs supported by the support extends along the orthogonal direction, and
the measurement system is translated along the orthogonal direction while continuously measuring the characteristics of the layers of the particular ICE along the orthogonal direction.

24. The system of claim 20, wherein the measurement system comprises an ellipsometer to measure polarization components of the probe-light interacted with the layers of the ICEs, such that the measured polarization components are spatially-resolved along the orthogonal direction.

25. The system of claim 20, wherein the measurement system comprises an optical monitor to measure change of intensity of the probe-light interacted with the layers of the ICEs, such that the measured change of intensity is spatially-resolved along the orthogonal direction.

26. The system of claim 20, wherein the measurement system comprises a spectrometer to measure spectra of the probe-light interacted with the layers of the ICEs, such that the spectra are spatially-resolved along the orthogonal direction.
